(19) United States
(12) Patent Application Publication
(10) Pub. No.: US 2026/0271557 A1
(43) Pub. Date: Sep. 10, 2026

(54) DISPLAY DEVICE, ELECTRONIC DEVICE, AND METHOD OF MANUFACTURING THE DISPLAY DEVICE

(71) Applicant: Samsung Display Co., Ltd., Yongin-si (KR)

(72) Inventors: Sun Kwang KIM, Yongin-si (KR); Si Hyun AHN, Yongin-si (KR); Kye Uk LEE, Yongin-si (KR); Seong Young LEE, Yongin-si (KR); Kang Moon JO, Yongin-si (KR)

(73) Assignee: Samsung Display Co., Ltd., Yongin-si (KR)

(21) Appl. No.: 19/338,178

(22) Filed: Sep. 24, 2025

(30) Foreign Application Priority Data
Mar. 7, 2025 (KR) 10-2025-0029779

(51) Int. Cl. H10K 59/131; H10K 50/19; H10K 59/12; H10K 59/122; H10K 71/60

(52) U.S. Cl. CPC H10K 59/131; H10K 59/1201; H10K 59/122; H10K 71/60; H10K 50/19

(57) ABSTRACT

A display device includes a substrate including a display area and a non-display area, pixels located on the substrate in the display area, signal lines located on the substrate in the non-display area, and an organic structure located on a plurality of signal lines among the signal lines and including division patterns having a shape corresponding to that of the plurality of signal lines.

This application claims the benefit of Korean Patent Application No. 10-2025-0029779, filed on Mar. 7, 2025, in the Korean Intellectual Property Office, the disclosure of which is incorporated herein in its entirety by reference.

### BACKGROUND

### 1. Field

Example embodiments of the present disclosure relate to display devices and/or electronic devices which can display an image, and/or methods of manufacturing the display device.

### 2. Description of the Related Art

As the information society develops, demands for display devices and electronic devices, which can display images, are increasing in various forms. Accordingly, various types of display devices and electronic devices, which include pixels for displaying images, are being developed. The display devices may be provided alone or may be included in the electronic devices and used as display screens of the electronic devices.

### SUMMARY

Some example embodiments of the present disclosure provide display devices and/or electronic devices which can reduce or prevent image quality defects caused by a difference between electrical characteristics of signal lines and/or methods of manufacturing the display device.

However, example embodiments of the present disclosure are not restricted to the one set forth herein. The above and other example embodiments of the present disclosure will become more apparent to one of ordinary skill in the art to which the present disclosure pertains by referencing the detailed description of the present disclosure given below.

According to an example embodiment of the present disclosure, a display device includes a substrate including a display area and a non-display area, pixels on the substrate in the display area, signal lines on the substrate in the non-display area, and an organic structure on a plurality of signal lines among the signal lines, the organic structure including division patterns, the division patterns having a shape corresponding to that of the plurality of signal lines.

In an example embodiment, the plurality of signal lines may include a first signal line and a second signal line arranged in series in a first direction, and the division patterns may include a first division pattern and a second division pattern, the first division pattern and the second division pattern on the first signal line and the second signal line, respectively, and spaced apart from each other in the first direction.

In an example embodiment, the display device may further include a gate driver on the substrate and in the non-display area, the gate driver electrically connected to the first signal line and the second signal line, wherein the first signal line and the second signal line may be clock signal lines configured to receive different clock signals.

In an example embodiment, the organic structure may surround the display area and the gate driver.

In an example embodiment, the organic structure may include a number of division patterns corresponding to a number of the plurality of signal lines.

In an example embodiment, each of the division patterns may include a first organic pattern on each of the plurality of signal lines, an inorganic pattern covering an upper surface of the first organic pattern, and a second organic pattern on the first organic pattern and the inorganic pattern.

In an example embodiment, the inorganic pattern may include a plurality of openings.

In an example embodiment, the first organic pattern may have a shape corresponding to that of the inorganic pattern and may be opened in areas corresponding to the plurality of openings.

In an example embodiment, the first organic pattern may have a first height under a central portion of the inorganic pattern and a second height under both ends of the inorganic pattern, the second height being lower than the first height.

In an example embodiment, the display device may further include, an insulating layer between the signal lines and the organic structure and covering the signal lines, and an organic layer on the insulating layer in the display area, wherein each of the pixels may include a light emitting element, the light emitting element including a first electrode, a light emitting layer and a second electrode sequentially located on the organic layer.

In an example embodiment, the first organic pattern may be on the insulating layer and may include a same material as the organic layer, and the inorganic pattern may include a same material as the first electrode included in the light emitting element.

In an example embodiment, the display device may further include a pixel defining layer on the organic layer in the display area and covering an edge portion of the first electrode of the light emitting element, and the second organic pattern may include a same material as the pixel defining layer.

In an example embodiment, the division patterns may be entirely separated from each other and may sequentially surround the display area.

In an example embodiment, in one portion of the non-display area that overlaps the plurality of signal lines, the organic structure may be divided into the division patterns, and in another portion of the non-display area, the organic structure is provided as an integral structure by integrating, portions extending from the division patterns.

According to an example embodiment of the present disclosure, an electronic device includes a display module including a display panel, and a processor configured to transmit an image data signal to the display module, wherein the display panel includes a substrate including a display area and a non-display area, pixels on the substrate in the display area, signal lines on the substrate in the non-display area, and an organic structure on a plurality of signal lines among the signal lines, the organic structure including division patterns, the division patterns having a shape corresponding to that of the plurality of signal lines.

In an example embodiment, the plurality of signal lines may include a first signal line and a second signal line arranged in series in a first direction, and the division patterns may include a first division pattern and a second division pattern, the first division pattern and the second division pattern being on the first signal line and the second signal line, respectively, and spaced apart from each other in the first direction.

In an example embodiment, each of the division patterns may include a first organic pattern on each of the plurality of signal lines, an inorganic pattern covering an upper surface of the first organic pattern, and a second organic pattern on the first organic pattern and the inorganic pattern.

According to an example embodiment of the present disclosure, a method of manufacturing a display device includes sequentially forming signal lines, an insulating layer and an organic structure on a substrate, the forming of the organic structure including forming an organic film on the insulating layer, the organic film including a first portion having a first height and a second portion having a second height lower than the first height, forming inorganic patterns on a first area of the organic film that includes the first portion and to be spaced apart from each other in a first direction, forming first organic patterns under the inorganic patterns by removing a second area of the organic film that is not covered with the inorganic patterns, by an ashing process using the inorganic patterns as a mask, and forming second organic patterns on the first organic patterns and the inorganic patterns and to be spaced apart from each other in the first direction.

In an example embodiment, the first organic patterns, the inorganic patterns and the second organic patterns may be formed on a plurality of signal lines that are arranged in series in the first direction, and may be divided into shapes corresponding to the plurality of signal lines.

In an example embodiment, the first organic patterns and the inorganic patterns may be formed on respective ones of the signal lines and include a plurality of openings.

According to display devices, electronic devices, and/or methods of manufacturing the display device in the above example embodiments, an organic structure located on signal lines of a non-display area is divided into shapes corresponding to the signal lines. Therefore, image quality defects caused by a difference between electrical characteristics of the signal lines can be prevented or improved. In some example embodiments, first organic patterns included in division patterns of the organic structure are covered with inorganic patterns. Therefore, the first organic patterns can be reduced or prevented from becoming vulnerable to moisture absorption, and/or a change in the electrical characteristics of the signal lines can be prevented or reduced.

According to the above example embodiments, the durability of the organic structure may be improved, and/or a change in the electrical characteristics of the signal lines may be reduced or prevented. Accordingly, the image quality and/or reliability of the display device and the electronic device can be improved.

However, effects according to the above example embodiments of the present disclosure are not limited to those described above, and various other effects may be achieved.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a plan view of a display device according to an example embodiment;

FIG. 2 is a plan view of a display panel of FIG. 1;

FIG. 3 is an equivalent circuit diagram of a pixel according to an example embodiment;

FIG. 4 is a schematic diagram of a gate driver according to an example embodiment;

FIG. 5 is a cross-sectional view of a display panel according to an example embodiment;

FIG. 6 is an enlarged view of area A1 of FIG. 5;

FIG. 7 is a cross-sectional view of the display panel according to an example embodiment;

FIG. 8 is an enlarged view of area A2 of FIG. 7;

FIG. 9 is a plan view illustrating signal lines and an organic structure according to an example embodiment;

FIG. 10 is a plan view illustrating signal lines and an organic structure according to an example embodiment;

FIG. 11 is a plan view illustrating signal lines and an organic structure according to an example embodiment;

FIG. 12 is a plan view illustrating signal lines and an organic structure according to an example embodiment;

FIG. 13 is an enlarged view of area A3 of FIG. 12 according to an example embodiment;

FIG. 14 shows a cross-sectional view of signal lines and an organic structure taken along line X1-X1′ of FIG. 12 according to an example embodiment of cross-sections;

FIG. 15 is an enlarged view of area A3 of FIG. 12 according to an example embodiment;

FIG. 16 is an enlarged view of area A3 of FIG. 12 according to an example embodiment;

FIG. 17 is an enlarged view of area A3 of FIG. 12 according to an example embodiment;

FIG. 18 shows an embodiment of cross-sections of signal lines and an organic structure taken along line X1-X1′ of FIG. 12;

FIG. 19 is a plan view of a display panel including an organic structure according to an example embodiment;

FIG. 20 is a plan view of a display panel including an organic structure according to an example embodiment;

FIG. 21 is a plan view of a display panel including an organic structure according to an example embodiment;

FIG. 22 is a plan view of a display panel including an organic structure according to an example embodiment;

FIGS. 23 through 26 are cross-sectional views illustrating a method of manufacturing a display device according to an example embodiment;

FIGS. 27 through 30 are cross-sectional views illustrating a method of manufacturing a display device according to an example embodiment;

FIG. 31 is a block diagram of an electronic device according to an example embodiment; and

FIG. 32 is a schematic diagram of electronic devices according to various example embodiments.

### DETAILED DESCRIPTION

The present inventive concepts will now be described more fully hereinafter with reference to the accompanying drawings, in which some example embodiments of the present inventive concepts are shown. The inventive concepts may, however, be embodied in different forms and should not be construed as limited to the example embodiments set forth herein. Rather, these example embodiments are provided so that this disclosure will be thorough and complete, and will fully convey the scope of the inventive concepts to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concepts. Similarly, the second element could also be termed the first element.

Features of each of various example embodiments of the present disclosure may be partially or entirely combined with each other and may technically variously interwork with each other, and respective example embodiments may be implemented independently of each other or may be implemented together in association with each other.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

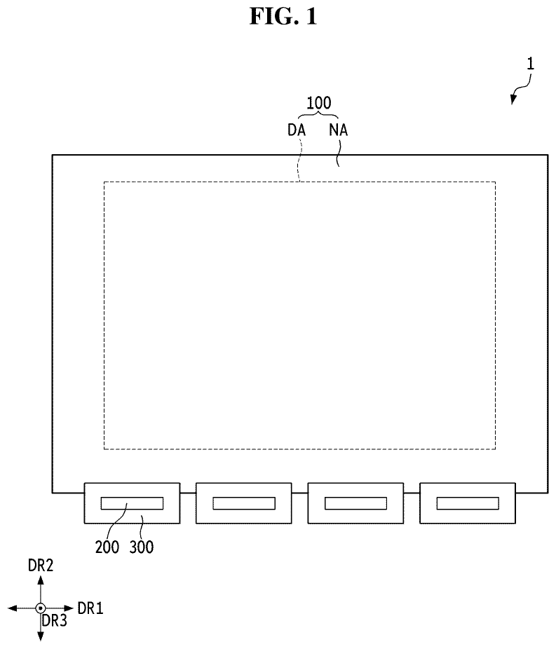

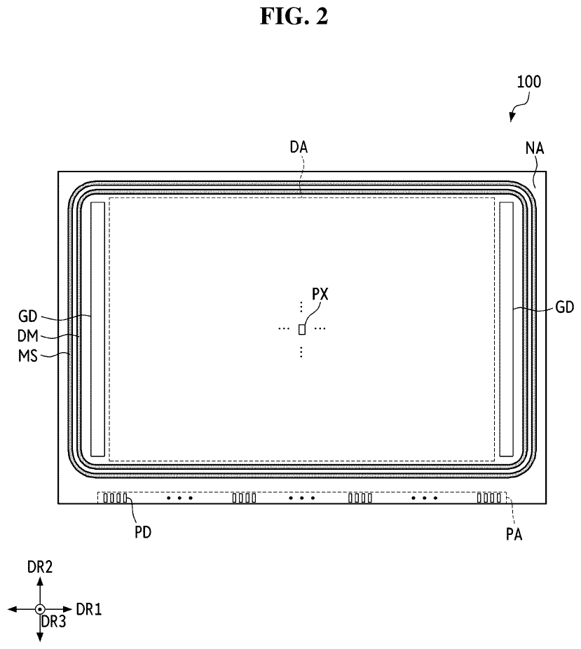

FIG. 1 is a plan view of a display device 1 according to an example embodiment. FIG. 2 is a plan view of a display panel 100 of FIG. 1.

Referring to FIGS. 1 and 2, the display device 1 is a device that displays a moving image or a still image. The display device 1 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various electronic devices such as televisions, notebook computers, monitors, billboards and Internet of things (IoT) devices. These are presented only as examples, and the display device 1 may also be employed in other types or forms of electronic devices. For example, the display device 1 may be included in other electronic devices such as a virtual reality (VR) device and an augmented reality (AR) device and may be used to display images in the electronic devices. In an example embodiment, an electronic device including the display device 1 may further include a housing or case for storing and/or protecting the display device 1 (or a display module including the display panel 100).

In an example embodiment, the display device 1 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro- or nano-light emitting diode (LED). However, example embodiments are not limited to such light emitting display devices. For example, the display device 1 may also be a type of display device other than a light emitting display device. Some example embodiments in which the display device 1 is an organic light emitting display device are disclosed below.

The display device 1 may include the display panel 100, which includes pixels PX, and a gate driver GD (also referred to as a “first driver”) and a data driver 200 (also referred to as a “second driver” or a “source driver”), which supply driving signals to the pixels PX. The display device 1 may further include additional elements. For example, the display device 1 may further include a power supply unit (also referred to as a “power supply”) for supplying driving voltages to the pixels PX, the gate driver GD and the data driver 200 and a timing controller for controlling the operations of the gate driver GD and the data driver 200.

The display panel 100 may include a display area DA and a non-display area NA. The display area DA is an area where the pixels PX are located and may be an area where an image is displayed by the pixels PX. The non-display area NA is an area other than the display area DA, and an image may not be displayed in the non-display area NA. In an example embodiment, the non-display area NA may be located around the display area DA and may surround the display area DA.

In an example embodiment, the display panel 100 may have a substantially rectangular planar shape (e.g., a rectangular shape whose horizontal length is greater than a vertical length). However, example embodiments are not limited to this case. For example, the display panel 100 may also have a square shape, a non-tetragonal polygonal shape, a circular shape, an elliptical shape, or other shapes in plan view. In addition, the display panel 100 may include angled corners or rounded corners.

In FIGS. 1 and 2, a first direction DR1, a second direction DR2, and a third direction DR3 are defined. In an example embodiment, the first direction DR1 may be a horizontal direction of the display panel 100, and the second direction DR2 may be a vertical direction of the display panel 100 (e.g., a horizontal direction perpendicular to the first direction DR1). The third direction DR3 may be a thickness direction of the display panel 100 (e.g., a direction perpendicular to the display panel 100).

In an example embodiment, the display panel 100 may be substantially flat in a plane defined by the first direction DR1 and the second direction DR2 and may have a uniform thickness in the third direction DR3. In an example embodiment, the display panel 100 may include a curved surface or may have a thickness that gradually changes in at least one portion.

The display area DA may have various shapes depending on example embodiments. For example, the display area DA may have a quadrangular shape, a non-quadrangular polygonal shape, a circular shape, an elliptical shape, or other shapes.

The pixels PX may be located in the display area DA. In an example embodiment, each pixel PX may include a light emitting element and a pixel circuit connected to the light emitting element. In the present disclosure, the term “connection” may include the meaning of electrical connection and/or physical connection. Each pixel circuit may include circuit elements for controlling a light emitting element (e.g., transistors including a driving transistor, which generates a driving current corresponding to a data signal, and at least one switching transistor, a capacitor storing a data signal, etc.).

The non-display area NA may be located outside the display area DA. For example, the non-display area NA may include an edge portion of the display panel 100.

In an example embodiment, at least one driving circuit may be located in the non-display area NA. For example, the gate driver GD may be located in the non-display area NA.

In an example embodiment, the gate driver GD may be formed inside the display panel 100 together with the pixels PX. In some example embodiments, the display panel 100 may include the pixels PX located in the display area DA and at least one gate driver GD located in the non-display area NA. The display panel 100 may further include wirings located in the display area DA and the non-display area NA. Each wiring may be electrically connected to at least one of the pixels PX, the gate driver GD, and/or pads PD.

The gate driver GD may be located on at least one side of the display area DA. For example, the display device 1 may include two gate drivers GD located on left and right sides of the display area DA, but example embodiments are not limited to this example.

The gate drivers GD may be electrically connected to the pixels PX through wirings (e.g., gate lines including scan lines) connected between the pixels PX and the gate drivers GD. In addition, the gate drivers GD may be electrically connected to a control circuit such as the timing controller through the pads PD, etc. and may be supplied with gate control signals. For example, the gate drivers GD may be electrically connected to the timing controller through a plurality of pads PD located in a pad area PA and may be supplied with gate control signals from the timing controller. The gate drivers GD may output gate signals (e.g., scan signals) in response to the gate control signals. The gate signals (e.g., scan signals) may be transmitted to the pixels PX through the respective gate lines.

The non-display area NA may include the pad area PA in which the pads PD are located. The pads PD may include signal pads and power pads for transmitting driving signals and driving voltages necessary or desired for driving the display panel 100 to the display panel 100.

In an example embodiment, the display panel 100 may further include a dam structure DM and an organic structure MS located in the non-display area NA. The dam structure DM and the organic structure MS may be separated from each other.

The dam structure DM may include at least one dam surrounding the display area DA. In an example embodiment, the dam structure DM may further surround portions of the non-display area NA where the gate drivers GD are located.

The organic structure MS may be located outside the dam structure DM. For example, the organic structure MS may be located closer to edges of the display panel 100 than the dam structure DM and may surround the dam structure DM. Although FIG. 2 discloses an example embodiment in which the organic structure MS is shaped like a closed loop that completely surrounds the dam structure DM, example embodiments are not limited to this case. For example, the organic structure MS may also be composed of division patterns located around different parts of the dam structure DM.

The organic structure MS may be utilized as a support for supporting a mask which is used in each process for forming light emitting elements, an encapsulation layer, etc. of the display panel 100. The organic structure MS may also be referred to as a “mask support.” The mask, which is mounted or bonded onto the organic structure MS, may include an opening for defining or limiting a formation area or range of a specific element included in the light emitting elements, the encapsulation layer, etc. For example, when a light emitting layer of the light emitting elements is to be formed in the form of a common layer in the display area DA, a mask used to form the light emitting layer may include an opening exposing the entire display area DA and a frame surrounding the opening. The opening may have a size and shape corresponding to those of an area where the light emitting layer is to be formed. The frame of the mask may include a bonding portion which protrudes downward at a position corresponding to the organic structure MS and is bonded and/or mounted on the organic structure MS. For example, the frame of the mask may include a bonding portion which protrudes from a lower surface in a shape corresponding to a shape and/or size of the organic structure MS. The bonding portion may have an island shape or a ring shape in plan view.

In an example embodiment, the organic structure MS may include an organic material. Accordingly, the organic structure MS may have a buffering function. For example, when the mask and the organic structure MS are bonded, even if impact or pressure is applied to the organic structure MS, a defect such as a crack may not occur in the organic structure MS. In addition, the organic structure MS may prevent or alleviate impact from being applied to a lower panel or a backplane layer of the display panel 100 by absorbing or alleviating the impact. Accordingly, the lower panel or the backplane layer of the display panel 100 can be protected.

At least one circuit board 300 may be placed on the pads PD. At least one driving circuit may be placed on the circuit board 300. For example, a data driver 200 may be placed on the circuit board 300.

In an example embodiment, the display device 1 may include a plurality of circuit boards 300 located on different pads PD and a plurality of data drivers 200 located on the circuit boards 300.

The data drivers 200 may be connected to data lines of the display area DA through the pads PD electrically connected to the circuit boards 300 and wirings (e.g., data connection wirings) electrically connected to the pads PD. The data drivers 200 may be electrically connected to the pixels PX through the data lines. In addition, the data drivers 200 may be electrically connected to a control circuit such as the timing controller and may be supplied with image data and data control signals. The data drivers 200 may output data signals in response to the image data and the data control signals. The data signals may be transmitted to the pixels PX through the respective data lines.

In an example embodiment, the timing controller may be located or provided outside the display panel 100 and may be electrically connected to the display panel 100. For example, the timing controller may be placed on a circuit board 300 on which a data driver 200 is located or may be placed on another circuit board electrically connected to the display panel 100. The timing controller may be integrated with the data driver 200 or may be provided separately from the data driver 200.

The circuit board 300 may be electrically connected to the display panel 100 through the pads PD. In an example embodiment, the circuit board 300 may be, but is not limited to, a flexible printed circuit board (FPCB), a printed circuit board (PCB), or a flexible film such as a chip on film (COF). In an example embodiment, the circuit board 300 may be connected to the timing controller and/or the power supply unit through another circuit board or a connector.

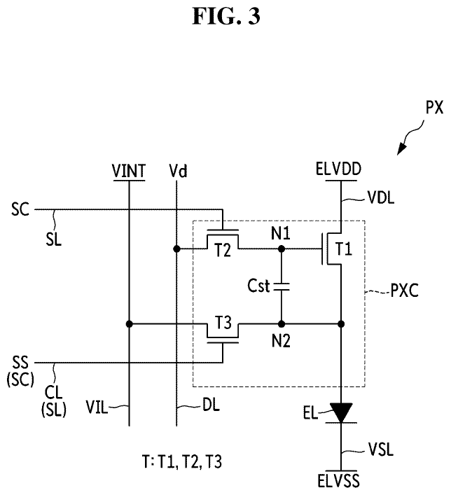

FIG. 3 is an equivalent circuit diagram of a pixel PX according to an example embodiment. For example, FIG. 3 shows an example embodiment of a pixel PX including a light emitting element EL. The type and/or structure of the pixel PX that may be included in the display device 1 may vary depending on example embodiments.

Referring to FIG. 3, the pixel PX according to the example embodiment may include a light emitting element EL and a pixel circuit PXC. The light emitting element EL may be, but is not limited to, an organic light emitting diode. The pixel circuit PXC may be electrically connected to the light emitting element EL to control the light emission of the light emitting element EL.

The pixel circuit PXC may include transistors T and a capacitor Cst. For example, the pixel circuit PXC may include a first transistor T1, a second transistor T2, a third transistor T3, and the capacitor Cst. Although FIG. 3 illustrates an embodiment in which all of the transistors T are N-type transistors, the types of the transistors T are not limited to an N type. For example, at least one transistor T may be formed as a P-type transistor.

The pixel circuit PXC may supply a driving current to the light emitting element EL in response to driving signals supplied from a gate driver GD and a data driver 200. For example, the pixel circuit PXC may supply a driving current to the light emitting element EL in response to a scan signal SC and a control signal SS supplied from the gate driver GD through a scan line SL and a control line CL, respectively, and a data signal Vd supplied from the data driver 200 through a data line DL.

Although FIG. 3 illustrates an example embodiment in which the scan line SL and the control line CL are separated from each other, example embodiments are not limited to this case. In some example embodiments, the control line CL may branch from the scan line SL as a part of the scan line SL, and the control signal SS may be the same as the scan signal SC.

The first transistor T1 may be a driving transistor of the pixel PX in which the magnitude of a drain-source current (e.g., a driving current) is determined according to a gate-source voltage. The second and third transistors T2 and T3 may be switching transistors which are turned on or off according to their respective gate-source voltages. Depending on the type of each of the transistors T (e.g., a P-type or N-type transistor) and/or operating conditions, a first electrode of each of the transistors T may be a drain electrode (or a drain region) or a source electrode (or a source region), and a second electrode may be an electrode different from the first electrode. For example, when the first electrode is a drain electrode, the second electrode may be a source electrode.

The pixel PX may be connected to the scan line SL which transmits the scan signal SC, the control line CL which transmits the control signal SS (e.g., a sensing control signal or an initialization control signal), and the data line DL which transmits the data signal Vd. In addition, the pixel PX may be connected to a first power line VDL which transmits a first driving voltage ELVDD (also referred to as a “first pixel voltage”) and a second power line VSL which transmits a second driving voltage ELVSS (also referred to as a “second pixel voltage”). A level of the second driving voltage ELVSS may be lower than a level of the first driving voltage ELVDD. In an example embodiment, the pixel PX may be further connected to an initialization power line VIL (or a sensing line) which transmits an initialization voltage VINT (also referred to as a “third pixel voltage”).

In an example embodiment, the transistors T may be oxide transistors including an oxide semiconductor. For example, an active layer of each of the first, second and third transistors T1, T2 and T3 may include an oxide semiconductor. However, example embodiments are not limited to this example. For example, at least one transistor T may also include a semiconductor material (e.g., amorphous silicon or polysilicon) other than an oxide semiconductor.

The first transistor T1 may include a gate electrode connected to a first node N1, a first electrode (e.g., a drain electrode) connected to the first power line VDL, and a second electrode (e.g., a source electrode) connected to a second node N2. The second node N2 may be a node to which the pixel circuit PXC and the light emitting element EL are connected. The first transistor T1 may control the driving current of the pixel PX in response to the data signal Vd transmitted to the first node N1.

The second transistor T2 may include a gate electrode connected to the scan line SL, a first electrode connected to the data line DL, and a second electrode connected to the first node N1. The second transistor T2 may be turned on by the scan signal SC of a gate-on voltage (e.g., a relatively high-level voltage or a voltage higher than a threshold voltage) applied to the scan line SL to connect the data line DL and the first node N1. Accordingly, the data signal Vd applied to the data line DL may be transmitted to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by the control signal SS (or the scan signal SC) of a gate-on voltage applied to the control line CL (or the scan line SL) to connect the initialization voltage line VIL and the second node N2.

The capacitor Cst may be connected between the first node N1 and the second node N2. The capacitor Cst may be charged with a voltage corresponding to the data signal Vd (e.g., a data voltage) transmitted to the first node N1.

The light emitting element EL may be connected between the pixel circuit PXC and the second power line VSL. For example, the light emitting element EL may include a first electrode (e.g., an anode) connected to the pixel circuit PXC through the second node N2, a second electrode (e.g., a cathode) facing the first electrode and connected to the second power line VSL, and a light emitting layer located between the first electrode and the second electrode. In an example embodiment, the first electrode of the light emitting element EL may be a pixel electrode individually provided in each pixel PX, and the second electrode of the light emitting element EL may be a common electrode shared by a plurality of pixels PX. The light emitting element EL may emit light with a luminance corresponding to a driving current during a period in which the driving current is supplied from the pixel circuit PXC.

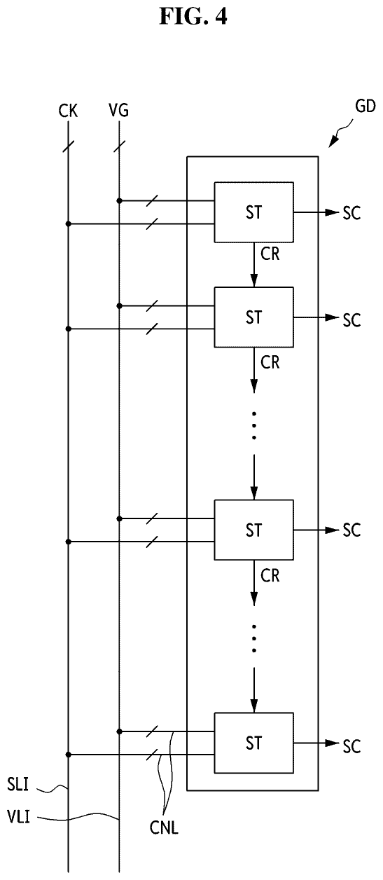

FIG. 4 is a schematic diagram of a gate driver GD according to an example embodiment. FIG. 4 schematically shows a scan driver, which outputs scan signals SC, as an element that may be included in the gate driver GD.

Referring to FIG. 4 in addition to FIGS. 1 through 3, the gate driver GD may include a plurality of stages ST which output scan signals SC, respectively. Each stage ST may receive at least one clock signal CK and at least one driving voltage VG from at least one signal line SLI and at least one driving voltage line VLI, respectively. For example, each stage ST may receive a plurality of clock signals CK (e.g., a plurality of clock signals CK having different waveforms and/or phases) and a plurality of driving voltages VG (e.g., a plurality of driving voltages VG including a gate-high voltage and a gate-low voltage) from a plurality of signal lines SLI and a plurality of driving voltage lines VLI, respectively, and may output its scan signal SC in response to the clock signals CK and the driving voltages VG.

In an example embodiment, the signal lines SLI and the driving voltage lines VLI of the gate driver GD may be located in the non-display area NA of FIGS. 1 and 2 and may be electrically connected between the pads PD and the gate driver GD. For example, the signal lines SLI and the driving voltage lines VLI of the gate driver GD may be located around the gate driver GD and may extend generally in the second direction DR2.

For example, as illustrated in FIG. 4, the signal lines SLI and the driving voltage lines VLI connected to the gate driver GD located on the left side of the display area DA may be located on a left side of the gate driver GD and may extend in the second direction DR2 around the gate driver GD. In addition, the signal lines SLI and the driving voltage lines VLI connected to the gate driver GD located on the right side of the display area DA may be located on a right side of the gate driver GD and may extend in the second direction DR2 around the gate driver GD. Ends (e.g., lower ends) of the signal lines SLI and the driving voltage lines VLI may extend to the pad area PA and may be electrically connected to the pads PD.

In an example embodiment, the signal lines SLI and the driving voltage lines VLI may be electrically connected to the stages ST by connection lines CNL, respectively. For example, in the non-display area NA of FIGS. 1 and 2, a plurality of connection lines CNL may be placed to electrically connect each of the signal lines SLI and the driving voltage lines VLI to at least one stage ST. The connection lines CNL may be located around the gate driver GD and may extend generally in the first direction DR1.

In an example embodiment, some of the stages ST included in the gate driver GD and some other stages ST may be driven by different clock signals CK. For example, at least one clock signal CK including a first clock signal may be input to some stages ST, and at least one other clock signal CK including a second clock signal different from the first clock signal may be input to some other stages ST.

In an example embodiment, the stages ST may form a shift register and sequentially output the scan signals SC. For example, a first stage ST may receive a start pulse through at least one wiring electrically connected to the timing controller (e.g., another signal line separated from the signal lines SLI to which the clock signals CK are applied) and may output a scan signal SC and a carry signal CR using the start pulse. The other stages ST may output their respective scan signals SC and carry signals CR using carry signals CR output from respective previous stages ST.

The type, structure, and/or number of stages ST included in the gate driver GD may vary depending on example embodiments. In addition, the types, waveforms, and/or numbers of input signals and output signals of the stages ST may vary depending on example embodiments.

In an example embodiment, the gate driver GD may be formed inside the display panel 100 together with the pixels PX. For example, the stages ST may include circuit elements such as transistors, and the circuit elements of the stages ST may be formed at the same time as the circuit elements of the pixels PX.

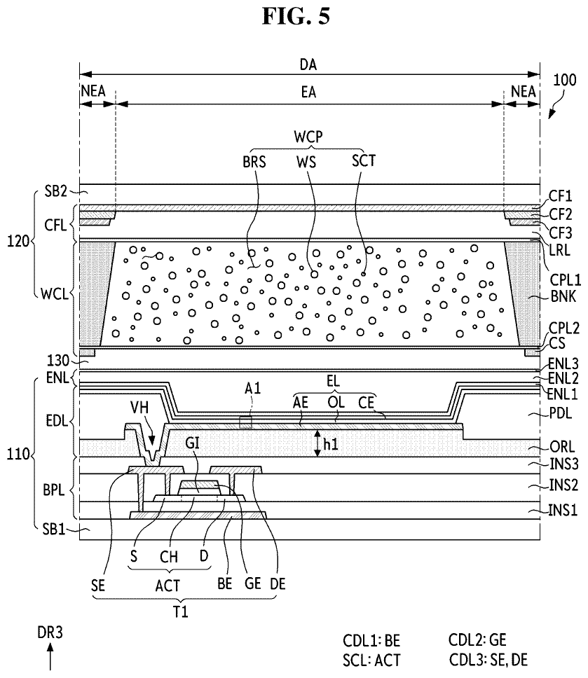

FIG. 5 is a cross-sectional view of a display panel 100 according to an example embodiment. For example, FIG. 5 schematically shows a cross-section of the display panel 100 in a portion of a display area DA where one pixel PX is located. FIG. 5 illustrates the display panel 100 having a structure in which a lower panel 110 including a first substrate SB1 is attached to an upper panel 120 including a second substrate SB2. However, the structure of the display panel 100 is not limited to this structure.

Referring to FIG. 5 in addition to FIGS. 1 through 4, the display panel 100 may include the first substrate SB1 (e.g., a lower substrate), a backplane layer BPL (e.g., a circuit layer of the display panel 100), a light emitting element layer EDL, and an encapsulation layer ENL. In an embodiment, the first substrate SB1, the backplane layer BPL, the light emitting element layer EDL, and the encapsulation layer ENL may form the lower panel 110 of the display panel 100. The backplane layer BPL, the light emitting element layer EDL, and the encapsulation layer ENL may be sequentially located on an upper surface of the first substrate SB1.

In an example embodiment, the display panel 100 may further include the second substrate SB2 (e.g., an upper substrate), a color filter layer CFL, a light conversion layer WCL, and a filler 130. In an example embodiment, the second substrate SB2, the color filter layer CFL, and the light conversion layer WCL may form the upper panel 120 of the display panel 100. The color filter layer CFL and the light conversion layer WCL may be sequentially located on a lower surface of the second substrate SB2. The filler 130 may fill a space between the lower panel 110 and the upper panel 120.

The first substrate SB1 is a base member for manufacturing the display panel 100 and may be a substrate including a rigid or flexible material (e.g., a glass substrate or a plastic substrate such as a polyimide (PI) substrate). The first substrate SB1 may include a display area DA and a non-display area NA. Pixels PX may be located on the first substrate SB1 in the display area DA.

The backplane layer BPL (e.g., a thin-film transistor layer) may be located on the first substrate SB1. The backplane layer BPL may include circuit elements, which include transistors T and capacitors Cst of the pixels PX, and wirings (e.g., various signal lines and power lines). In an example embodiment, the backplane layer BPL may further include circuit elements of a gate driver GD (e.g., transistors and/or capacitors included in stages ST) and/or additional conductive patterns (e.g., bridge patterns).

FIG. 5 shows a schematic form of a first transistor T1 included in one pixel PX as an example of circuit elements that may be included in the backplane layer BPL. Although FIG. 5 discloses an example embodiment in which the backplane layer BPL is directly located on the first substrate SB1, example embodiments are not limited to this case. For example, the display panel 100 may further include a barrier layer located on the first substrate SB1, and the backplane layer BPL may be located on the barrier layer.

The backplane layer BPL may include a plurality of conductive layers and at least one semiconductor layer SCL. The conductive layers may include electrodes, which form the circuit elements of the backplane layer BPL, and conductive patterns (e.g., bridge electrodes) and/or wirings, which are connected to the circuit elements. The semiconductor layer SCL may include active layers ACT included in the transistors T of the backplane layer BPL.

In an example embodiment, the backplane layer BPL may include a first conductive layer CDL1 (e.g., a bottom conductive layer), the semiconductor layer SCL, a second conductive layer CDL2 (e.g., a gate conductive layer), and a third conductive layer CDL3 (e.g., a source-drain conductive layer) sequentially located on the first substrate SB1 along the third direction DR3. In an example embodiment, the backplane layer BPL may further include at least one conductive layer located on the third conductive layer CDL3 and at least one insulating layer covering the at least one conductive layer. The at least one conductive layer may include a bridge electrode, which connects a light emitting element EL and a pixel circuit PXC (e.g., the first transistor T1) of each pixel PX, and/or at least one wiring.

Patterns included in each conductive layer of the backplane layer BPL (e.g., electrodes, conductive patterns, and/or wirings of each conductive layer) may include a conductive material. For example, patterns provided in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or an alloy thereof, or other conductive materials. In an example embodiment, patterns included in the same conductive layer may be simultaneously formed using the same conductive material.

In an example embodiment, the patterns provided in each conductive layer of the backplane layer BPL may have a single-layer or multilayer structure. For example, the patterns provided in each of the first conductive layer CDL1, the second conductive layer CDL2, and the third conductive layer CDL3 may have a single-layer or multilayer structure. In an example embodiment, the patterns included in the same conductive layer may have the same cross-sectional structure.

The backplane layer BPL may further include a plurality of insulating layers and/or insulating patterns located on the first substrate SB1. For example, the backplane layer BPL may include a first insulating layer INS1, a gate insulating layer GI, a second insulating layer INS2, and a third insulating layer INS3 sequentially located on the first substrate SB1 along the third direction DR3.

In an example embodiment, at least one insulating layer included in the backplane layer BPL may be located in the entire display area DA. For example, the first insulating layer INS1, the second insulating layer INS2, and the third insulating layer INS3 may be located in the entire display area DA.

The first conductive layer CDL1 may include a bottom electrode BE. The bottom electrode BE may be located under the active layer ACT of the first transistor T1. For example, the bottom electrode BE may be located under the active layer ACT of the first transistor T1 to overlap a channel region CH of the first transistor T1. Because the bottom electrode BE is located under the channel region CH of the first transistor T1, it may block external light from being incident on the channel region CH of the first transistor T1 and may stabilize the operating characteristics of the first transistor T1.

In an example embodiment, the bottom electrode BE may be electrically connected to an electrode of the first transistor T1 and may be utilized to control the characteristics of the first transistor T1. For example, the bottom electrode BE may be electrically connected to a source electrode SE of the first transistor T1. In this case, the bottom electrode BE may be considered as an element included in the first transistor T1.

The first insulating layer INS1 may be located on the first conductive layer CDL1. For example, the first insulating layer INS1 may be located on the first substrate SB1 to cover the patterns of the first conductive layer CDL1. The first insulating layer INS1 may include at least one inorganic insulating layer including an inorganic insulating material (e.g., silicon nitride, silicon oxide, silicon oxynitride, titanium oxide, aluminum oxide, or other inorganic insulating materials).

The semiconductor layer SCL may be located on the first insulating layer INS1. The semiconductor layer SCL may include the active layers ACT of transistors (e.g., the transistors T of the pixels PX and/or transistors of the stages ST) included in the backplane layer BPL. For example, the semiconductor layer SCL may include the active layer ACT of the first transistor T1.

Each active layer ACT may include a channel region CH overlapping a gate electrode GE and a source region S and a drain region D located on opposite sides of the channel region CH. For example, the source region S and the drain region D may be spaced apart from each other with the channel region CH interposed therebetween. The channel region CH may be located between the source region S and the drain region D. The source region S and the drain region D may have higher conductivity than the channel region CH. For example, the source region S and the drain region D may have higher carrier concentration (e.g., electron concentration) than the channel region CH.

In an example embodiment, the active layers ACT may include an oxide semiconductor. For example, the active layers ACT may include an oxide semiconductor including at least one of indium (In), gallium (Ga), zinc (Zn), tin (Sn) or hafnium (Hf) or may include other oxide semiconductors. For example, the active layers ACT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO) or indium-tin-gallium-zinc oxide (ITGZO) or may include other oxide semiconductors. However, example embodiments are not limited to this example. For example, the active layers ACT may also include amorphous silicon or polysilicon.

The gate insulating layer GI may cover at least a portion of each of the active layers ACT included in the backplane layer BPL. For example, the gate insulating layer GI may cover the channel region CH of each of the active layers ACT. The gate insulating layer GI may include at least one inorganic insulating layer including an inorganic insulating material.

In an example embodiment, the gate insulating layer GI may be located in each pixel area and a portion of the display area DA including the pixel areas. For example, the gate insulating layer GI may be located only on a portion (e.g., the channel region CH) of each active layer ACT included in the semiconductor layer SCL and may not be located on the other portion (e.g., the source region S and the drain region D) of each active layer ACT. However, example embodiments are not limited to this example. For example, the gate insulating layer GI may also be located in the entire display area DA to entirely cover the patterns of the semiconductor layer SCL and the first insulating layer INS1.

The second conductive layer CDL2 may be located on the gate insulating layer GI. The second conductive layer CDL2 may include the gate electrode GE of each of the transistors included in the backplane layer BPL. For example, the second conductive layer CDL2 may include the gate electrode GE of the first transistor T1. The gate electrode GE of the first transistor T1 may be located on the gate insulating layer GI to overlap the channel region CH of the first transistor T1.

The second insulating layer INS2 may be located on the first insulating layer INS1, the semiconductor layer SCL, the gate insulating layer GI, and the second conductive layer CDL2. For example, the second insulating layer INS2 may be located on the first insulating layer INS1 to cover the patterns of the semiconductor layer SCL, the gate insulating layer GI and the second conductive layer CDL2. The second insulating layer INS2 may include at least one inorganic insulating layer including an inorganic insulating material.

The third conductive layer CDL3 may be located on the second insulating layer INS2. In an example embodiment, the third conductive layer CDL3 may include a source electrode SE and a drain electrode DE of each of the transistors included in the backplane layer BPL. For example, the third conductive layer CDL3 may include the source electrode SE and the drain electrode DE of the first transistor T1. The source electrode SE of the first transistor T1 may be electrically connected to the source region S of the first transistor T1 by penetrating the second insulating layer INS2. In an example embodiment, the source electrode SE of the first transistor T1 may also be electrically connected to the bottom electrode BE of the first transistor T1 by penetrating the first insulating layer INS1 and the second insulating layer INS2. The drain electrode DE of the first transistor T1 may be electrically connected to the drain region D of the first transistor T1 by penetrating the second insulating layer INS2.

In an example embodiment, at least one of the transistors included in the backplane layer BPL may not include a source electrode and/or a drain electrode, and the source region S and/or the drain region D of the active layer ACT included in the at least one transistor may be connected to other circuit elements, wirings, and/or conductive patterns to function as the source electrode and/or the drain electrode of the corresponding transistor. In this case, the third conductive layer CDL3 may include a conductive pattern electrically connected to the active layer ACT of the at least one transistor T.

The third insulating layer INS3 may be located on the third conductive layer CDL3. For example, the third insulating layer INS3 may be located on the second insulating layer INS2 to cover the patterns of the third conductive layer CDL3. The third insulating layer INS3 may include at least one inorganic insulating layer including an inorganic insulating material.

The light emitting element layer EDL may be located on the backplane layer BPL. For example, the light emitting element layer EDL may be located on the third insulating layer INS3 and may be located at least in the display area DA.

The light emitting element layer EDL may include light emitting elements EL of the pixels PX. For example, the light emitting element layer EDL may include a light emitting element EL located in an emission area EA of each of the pixels PX. The emission area EA is an area where the light emitting element EL of each pixel PX is located and may be a light transmitting area through which light generated by the light emitting element EL can pass.

The light emitting element layer EDL may further include a pixel defining layer PDL located around the light emitting elements EL of the pixels PX. For example, the pixel defining layer PDL may be located in a non-emission area NEA surrounding the emission areas EA of the pixels PX and may surround the light emitting element EL of each of the pixels PX when viewed in a plane defined by the first direction DR1 and the second direction DR2.

In an example embodiment, the light emitting element layer EDL may further include an organic layer ORL which covers the backplane layer BPL. Although the organic layer ORL is included in the light emitting element layer EDL in FIG. 5, example embodiments are not limited to this case. For example, the organic layer ORL may also be considered as being included in the backplane layer BPL. In this case, the light emitting element layer EDL may be located on the organic layer ORL.

The organic layer ORL may include at least one organic insulating layer including an organic insulating material (e.g., acryl resin, epoxy resin, phenolic resin, polyamide resin, polyimide resin, or other organic insulating materials). The organic layer ORL may reduce a step formed by the circuit elements or wirings of the backplane layer BPL in at least a portion of the display area DA. For example, under the light emitting element EL of each pixel PX, the organic layer ORL may reduce a step formed by the circuit elements of the backplane layer BPL and/or may be formed to a substantially uniform height (e.g., a first height h1) or thickness.

In an example embodiment, the organic layer ORL may have different heights (or thicknesses) at different portions. For example, the organic layer ORL may have the first height h1 (or a first thickness) at a portion covered with a first electrode AE of a light emitting element EL and may have a height lower than the first height h1 (or a thickness smaller than the first thickness) at a portion not covered with the first electrode AE of the light emitting element EL. The organic layer ORL and the third insulating layer INS3 may be removed from a contact portion for connecting the light emitting element EL and the first transistor T1. For example, the organic layer ORL and the third insulating layer INS3 may be opened in a portion where a via hole VH (or a contact hole) for connecting the first electrode AE of the light emitting element EL and the source electrode SE of the first transistor T1 is formed.

The light emitting elements EL of the pixels PX and the pixel defining layer PDL may be located on the organic layer ORL.

Each light emitting element EL may include the first electrode AE located in an emission area EA and a light emitting layer OL and a second electrode CE sequentially located on the first electrode AE. One of the first electrode AE or the second electrode CE of each light emitting element EL may be an anode, and the other may be a cathode. For example, the first electrode AE may be an anode, and the second electrode CE may be a cathode.

In an example embodiment, the first electrode AE may be a pixel electrode individually formed in each emission area EA. The first electrode AE may be connected to at least one transistor T included in a corresponding pixel PX. For example, the first electrode AE may be electrically connected to the source electrode SE of the first transistor T1 by penetrating the organic layer ORL and the third insulating layer INS3.

In an example embodiment, the display panel 100 may be a top emission display panel, and the first electrode AE may include a metal layer including a metal such as Ag, Mg, Al, Pt, Pd, Au, Ni, Nd, Ir, or Cr. In an example embodiment, the first electrode AE may further include a metal oxide layer overlapping the metal layer. For example, the first electrode AE may have a two-layer structure of ITO/Ag, Ag/ITO, ITO/Mg or ITO/MgF or a three-layer structure of ITO/Ag/ITO.

The pixel defining layer PDL may be located on a portion of the organic layer ORL. In an example embodiment, the pixel defining layer PDL may also be located on a portion of the first electrode AE included in each light emitting element EL. For example, the pixel defining layer PDL may cover an edge portion of the first electrode AE located in each emission area EA and may include an opening which exposes the other portion of the first electrode AE.

The pixel defining layer PDL may be located mainly in the non-emission area NEA and may have an opening corresponding to each emission area EA. In an example embodiment, the pixel defining layer PDL may also be located in an edge portion of each emission area EA.

In an example embodiment, the pixel defining layer PDL may include at least one organic insulating layer including an organic insulating material. For example, the pixel defining layer PDL may include an organic insulating material such as polyacrylates resin, epoxy resin, phenolic resin, polyamides resin, polyimides resin, unsaturated polyesters resin, polyphenylenethers resin, polyphenylenesulfides resin, or benzocyclobutene (BCB). However, the material of the pixel defining layer PDL is not limited to the above example.

The light emitting layer OL may be located on each first electrode AE. In an example embodiment, the light emitting layer OL may be in the form of a common layer formed continuously across the emission areas EA of the pixels PX and the non-emission area NEA. However, example embodiments are not limited to this case. For example, the light emitting layer OL may be individually formed in each emission area EA. For example, the light emitting layers OL of the light emitting elements EL according to an example embodiment may be formed separately from each other in the respective emission areas EA.

In an example embodiment, the light emitting layer OL may emit light of a third color, for example, blue light. However, example embodiments are not limited to this case. For example, the light emitting layer OL may emit white light.

The light emitting layer OL may be located mainly in the display area DA. In an example embodiment, the light emitting layer OL may extend to the non-display area NA outside the display area DA. Accordingly, an end of the light emitting layer OL may be located in the non-display area NA. In some example embodiments, the end of the light emitting layer OL may be located at a boundary between the display area DA and the non-display area NA.

Light emitted from the light emitting layer OL may contribute to image display. The light emitting layer OL will be described in detail later.

The second electrode CE may be located on the light emitting layer OL. In an example embodiment, the second electrode CE may be a common electrode shared by a plurality of pixels PX. For example, the second electrode CE may be formed in the entire display area DA including a plurality of emission areas EA (or in a portion of the display area DA).

In an example embodiment, the display panel 100 may be a top emission display panel, and the second electrode CE may have translucency or transparency. In an example embodiment, the second electrode CE may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg) and may have translucency. In an example embodiment, the second electrode CE may include tungsten oxide (WₓOₓ), titanium oxide (TiO₂), indium tin oxide (ITO), indium zinc oxide (IZO), zinc oxide (ZnO), indium tin zinc oxide (ITZO), or magnesium oxide (MgO) and may have transparency.

The first electrode AE, the light emitting layer OL, and the second electrode CE located in the emission area EA of each pixel PX may form the light emitting element EL of each pixel PX. In an example embodiment, the light emitting elements EL of the pixels PX may emit light of the same color. For example, the light emitting elements EL of a red pixel PX, a green pixel PX, and a blue pixel PX may be blue organic light emitting diodes which emit blue light. In an example embodiment, when the light emitting element EL included in at least one pixel PX emits light of a color different from an emission color (or emission wavelength) of the corresponding pixel PX, a light conversion member WCP including wavelength shifters WS may be placed on the light emitting element EL.

In an example embodiment, the light emitting element layer EDL may further include a capping layer which covers the second electrode CE. For example, the light emitting element layer EDL may further include a capping layer which is located on the second electrode CE and includes at least any one of an inorganic material or an organic material having light-transmitting properties. The capping layer may improve the viewing angle characteristics of the display panel 100 and/or improve external luminous efficiency.

The encapsulation layer ENL may be located on the light emitting element layer EDL. The encapsulation layer ENL may cover the light emitting element layer EDL in the display area DA and may extend to a portion of the non-display area NA which is adjacent to the display area DA.

The encapsulation layer ENL may block the penetration of oxygen or moisture into the light emitting element layer EDL and may mitigate electrical and/or physical impact on the backplane layer BPL and/or the light emitting element layer EDL. In an example embodiment, the encapsulation layer ENL may include a first encapsulation layer ENL1, a second encapsulation layer ENL2, and a third encapsulation layer ENL3 sequentially located on the light emitting element layer EDL.

Each of the first encapsulation layer ENL1 and the third encapsulation layer ENL3 may be an inorganic encapsulation layer including an inorganic material. For example, each of the first encapsulation layer ENL1 and the third encapsulation layer ENL3 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or lithium fluoride.

The second encapsulation layer ENL2 may be an organic encapsulation layer including an organic material. For example, the second encapsulation layer ENL2 may include acrylic resin, methacrylic resin, polyisoprene, vinyl resin, epoxy resin, urethane resin, cellulose resin, or perylene resin.

The second substrate SB2 may be located on the first substrate SB1 to cover elements (e.g., the backplane layer BPL, the light emitting element layer EDL, the encapsulation layer ENL, the light conversion layer WCL, and/or the color filter layer CFL) located between the first substrate SB1 and the second substrate SB2. The second substrate SB2 may be a substrate or a film including a rigid or flexible material.

The color filter layer CFL may be located on a surface (e.g., the lower surface) of the second substrate SB2 which faces the light emitting element layer EDL. In an example embodiment, the color filter layer CFL may be formed directly on the surface of the second substrate SB2. However, example embodiments are not limited to this case. For example, the color filter layer CFL may also be formed directly on the lower panel 110 (or the light conversion layer WCL).

The color filter layer CFL may include color filters which selectively transmit light corresponding to the emission color or emission wavelength of each of the pixels PX. For example, the color filter layer CFL may include a first color filter CF1 which transmits light of a first color, a second color filter CF2 which transmits light of a second color, and a third color filter CF3 which transmits light of a third color. In an example embodiment, the light of the first color, the light of the second color, and the light of the third color may be, but are not limited to, red light, green light, and blue light, respectively. The color filter layer CFL may further include a low refractive layer LRL and a first capping layer CPL1.

The first color filter CF1 may be located in the emission area EA of each of pixels PX which emit light of the first color. For example, the first color filter CF1 may be located in the emission area EA of each of red pixels which emit red light and may overlap the light emitting element EL of each of the red pixels.

The first color filter CF1 may selectively transmit light of the first color. For example, the first color filter CF1 may transmit light of the first color and absorb or block light of the third color. For example, when a red pixel includes a light emitting element EL which emits blue light and a light conversion member WCP which converts blue light into red light (e.g., a light transmitting member including wavelength shifters WS, which convert blue light into red light, and light scatterers SCT), the first color filter CF1 may transmit the red light into which a portion of the blue light emitted from the light emitting element LE of the red pixel has been converted by the light conversion member WCP of the red pixel and may absorb or block the blue light which has not been converted by the light conversion member WCP. Accordingly, the red light may be emitted from the emission area EA of the red pixel.

The second color filter CF2 may be located in the emission area EA of each of pixels PX which emit light of the second color. For example, the second color filter CF2 may be located in the emission area EA of each of green pixels which emit green light and may overlap the light emitting element EL of each of the green pixels.

The second color filter CF2 may selectively transmit light of the second color. For example, the second color filter CF2 may transmit light of the second color and absorb or block light of the third color. For example, when a green pixel includes a light emitting element EL which emits blue light and a light conversion member WCP which converts blue light into green light (e.g., a light transmitting member including wavelength shifters WS, which convert blue light into green light, and light scatterers SCT), the second color filter CF2 may transmit the green light into which a portion of the blue light emitted from the light emitting element LE of the green pixel has been converted by the light conversion member WCP of the green pixel and may absorb or block the blue light which has not been converted by the light conversion member WCP. Accordingly, the green light may be emitted from the emission area EA of the green pixel.

The third color filter CF3 may be located in the emission area EA of each of pixels PX which emit light of the third color. For example, the third color filter CF3 may be located in the emission area EA of each of blue pixels which emit blue light and may overlap the light emitting element EL of each of the blue pixels.

The third color filter CF3 may transmit light of the third color. For example, the third color filter CF3 may transmit light of the third color and absorb or block light of other colors. For example, when a blue pixel includes a light emitting element EL which emits blue light and a light conversion member WCP which transmits blue light (e.g., a light transmitting member including light scatterers SCT), the third color filter CF3 may transmit the blue light emitted from the light emitting element EL of the blue pixel and passing through the light conversion member WCP of the blue pixel. Accordingly, the blue light may be emitted from the emission area EA of the blue pixel.

In an example embodiment, the first color filter CF1, the second color filter CF2, and the third color filter CF3 may overlap each other in the non-emission area NEA. Accordingly, the first color filter CF1, the second color filter CF2, and the third color filter CF3 may form a light blocking pattern in the non-emission area NEA.

The low refractive layer LRL may be located on surfaces of the color filters. For example, the low refractive layer LRL may cover lower surfaces of the first color filter CF1, the second color filter CF2, and the third color filter CF3 which face the light emitting elements EL. The low refractive layer LRL may planarize a surface of the color filter layer CFL by compensating for a step difference caused by the first color filter CF1, the second color filter CF2, and the third color filter CF3.

In an example embodiment, the low refractive layer LRL may have a refractive index lower than a refractive index of the light conversion members WCP of the light conversion layer WCL. In an example embodiment, the refractive index of the low refractive layer LRL may be about 1.3 or less. As a difference between the refractive index of the low refractive layer LRL and the refractive index of the light conversion members WCP increases, total reflection of light may sufficiently occur between the low refractive layer LRL and the light conversion layer WCL. Accordingly, this may facilitate recycling of light generated by the pixels PX and increase the light efficiency of the pixels PX.

The first capping layer CPL1 may be located on a surface of the low refractive layer LRL. For example, the first capping layer CPL1 may cover a lower surface of the low refractive layer LRL which faces the light emitting element layer EDL. The first capping layer CPL1 may include a material suitable for protecting surrounding elements (e.g., other elements of the color filter layer CFL) from moisture or foreign substances. For example, the first capping layer CPL1 may include an inorganic material such as silicon nitride, silicon oxynitride, silicon oxide, titanium oxide, or aluminum oxide.

The light conversion layer WCL may be located on a surface (e.g., a lower surface) of the color filter layer CFL which faces the light emitting element layer EDL. In an example embodiment, the light conversion layer WCL may be formed directly on the second substrate SB2 or the surface of the color filter layer CFL. However, example embodiments are not limited to this case. For example, the light conversion layer WCL may also be formed directly on the lower panel 110. For example, the light conversion layer WCL may be formed directly on the encapsulation layer ENL.

The light conversion layer WCL may include a light conversion member WCP (or a light transmitting member) located in each of the emission areas EA and a bank BNK located in the non-emission area NEA. The light conversion layer WCL may further include a second capping layer CPL2 and a column spacer CS.

The light conversion member WCP may be a light transmitting member which can transmit light corresponding to the emission color or emission wavelength of each pixel PX. For example, the light conversion member WCP may include a light-transmitting base resin BRS.

The base resin BRS may include a light-transmitting organic material. For example, the base resin BRS may include epoxy resin, acrylic resin, cardo resin, or imide resin.

In an example embodiment, the light conversion member WCP may further include light scatterers SCT to increase the light efficiency of the pixels PX. For example, the light conversion member WCP may include light scatterers SCT such as titanium dioxide (TiO₂).

In an example embodiment, the light conversion member WCP located in the emission area EA of each of the pixels PX which emit light of specific colors may further include wavelength shifters WS. For example, when the light emitting element EL of each of the red pixels, the green pixels and the blue pixels is a blue-light emitting element which emits blue light, the light conversion member WCP located in the emission area EA of each of the red pixels may include wavelength shifters WS (e.g., red quantum dots) which convert blue light into red light, and the light conversion member WCP located in the emission area EA of each of the green pixels may include wavelength shifters WS (e.g., green quantum dots) which convert blue light into green light. Accordingly, the light conversion member WCP located in each red pixel may convert blue light into red light, and the light conversion member WCP located in each green pixel may convert blue light into green light. In an example embodiment, the wavelength shifters WS may be quantum dots (e.g., red quantum dots or green quantum dots), quantum rods, fluorescent materials, or phosphorescent materials.

The bank BNK may be located in the non-emission area NEA to define the emission areas EA in which the light conversion elements WCP are located. For example, the bank BNK may include openings corresponding to the emission areas EA of the pixels PX and may surround the emission areas EA.

In an example embodiment, the bank BNK may have a relatively thick thickness to provide spaces in which the light conversion elements WCP are formed. For example, the thickness of the bank BNK may be, but is not limited to, about 1 to about 10 μm.

In an example embodiment, the bank BNK may include an organic insulating material (e.g., acryl resin, epoxy resin, phenolic resin, polyamide resin, polyimide resin, or other organic insulating materials). In an example embodiment, the bank BNK may further include a light blocking material. For example, the bank BNK may include a dye or pigment having light-blocking properties (e.g., an inorganic black pigment, such as carbon black, or an organic black pigment). Accordingly, the bank BNK may have light-blocking properties.

The second capping layer CPL2 may be located on surfaces of the light conversion members WCP and the bank BNK. For example, the second capping layer CPL2 may cover lower surfaces of the light conversion members WCP and the bank BNK which face the light emitting element layer EDL. The second capping layer CPL2 may include a material suitable for protecting surrounding elements (e.g., other elements of the light conversion layer WCL) from moisture or foreign substances. For example, the second capping layer CPL2 may include an inorganic material such as silicon nitride, silicon oxynitride, silicon oxide, titanium oxide, or aluminum oxide.

The column spacer CS may be located on a surface of the second capping layer CPL2. The column spacer CS may be located in the non-emission area NEA to overlap at least a portion of the bank BNK. The column spacer CS may be, but is not limited to, a colored column spacer.

The filler 130 may fill the space formed between the lower panel 110 and the upper panel 120 of the display panel 100. The filler 130 may include a material having a relatively low extinction coefficient, for example, a light transmitting material having an extinction coefficient of substantially zero. A refractive index and an extinction coefficient are correlated, and the extinction coefficient may decrease as the refractive index decreases. When the refractive index is about 1.7 or less, the extinction coefficient may converge to substantially zero. In an example embodiment, the filler 130 may include a material having a refractive index of about 1.7 or less. Accordingly, light emitted from the light emitting elements EL can be reduced or prevented from being absorbed by the filler 130 as it passes through the filler 130, or the absorption of the light by the filler 130 can be reduced or minimized. In an example embodiment, the filler 130 may include an organic material having a refractive index of about 1.4 to about 1.6.

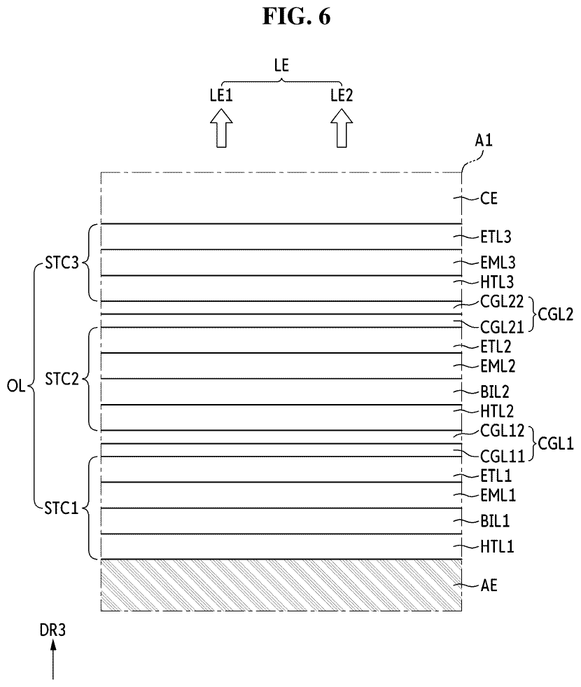

FIG. 6 is an enlarged view of area A1 of FIG. 5. For example, FIG. 6 shows a light emitting layer OL according to an example embodiment in detail.

Referring to FIGS. 5 and 6, the light emitting layer OL according to the example embodiment may be formed in a structure in which a plurality of light emitting material layers overlap, for example, in a tandem structure. In an example embodiment, the light emitting layer OL may include a first stack STC1 including a first light emitting material layer EML1, a second stack STC2 located on the first stack STC1 and including a second light emitting material layer EML2, a third stack STC3 located on the second stack STC2 and including a third light emitting material layer EML3, a first charge generation layer CGL1 located between the first stack STC1 and the second stack STC2, and a second charge generation layer CGL2 located between the second stack STC2 and the third stack STC3. The first stack STC1, the second stack STC2, and the third stack STC3 may overlap each other. However, the structure of the light emitting layer OL is not limited to the above structure. For example, the number of light emitting material layers and/or charge generation layers included in the light emitting layer OL may vary depending on example embodiments. For example, the light emitting layer OL may include a single light emitting material layer.

The first light emitting material layer EML1, the second light emitting material layer EML2, and the third light emitting material layer EML3 may overlap each other. In an example embodiment, the first light emitting material layer EML1, the second light emitting material layer EML2, and the third light emitting material layer EML3 may all emit light of the third color, for example, blue light. For example, each of the first light emitting material layer EML1, the second light emitting material layer EML2 and the third light emitting material layer EML3 may be a blue-light emitting layer and may include an organic material.

In an example embodiment, at least any one of the first light emitting material layer EML1, the second light emitting material layer EML2 or the third light emitting material layer EML3 may emit first blue light having a first peak wavelength, and at least another one of the first light emitting material layer EML1, the second light emitting material layer EML2 or the third light emitting material layer EML3 may emit second blue light having a second peak wavelength different from the first peak wavelength. In an example embodiment, any one of the first light emitting material layer EML1, the second light emitting material layer EML2 and or third light emitting material layer EML3 may emit the first blue light having the first peak wavelength, and the other two of the first light emitting material layer EML1, the second light emitting material layer EML2 and the third light emitting material layer EML3 may emit the second blue light having the second peak wavelength. For example, output light LE finally emitted from the light emitting layer OL may be a mixture of a first component LE1 and a second component LE2. Here, the first component LE1 may be the first blue light having the first peak wavelength, and the second component LE2 may be the second blue light having the second peak wavelength.

In an example embodiment, one of the first peak wavelength or the second peak wavelength may be in the range between about 440 and about 460 nm. The other one of the first peak wavelength or the second peak wavelength may be in the range between about 460 and about 480 nm. However, the range of the first peak wavelength and the range of the second peak wavelength are not limited to this example. For example, both the range of the first peak wavelength and the range of the second peak wavelength may be about 460 nm. In some example embodiments, any one of the first blue light or the second blue light may be light of a deep blue color, and the other one of the first blue light or the second blue light may be light of a sky blue color.

In an example embodiment, the output light LE emitted from the light emitting layer OL may be blue light and may include a relatively-long wavelength component and a relatively-short wavelength component. Therefore, the light emitting layer OL may emit blue light having a broader emission peak as the output light LE. Accordingly, this can improve color visibility at a side viewing angle compared with a display panel 100 using another light emitting element that emits blue light having a sharper emission peak.

In an example embodiment, each of the first light emitting material layer EML1, the second light emitting material layer EML2, and the third light emitting material layer EML3 may include a host and a dopant. The host may use, but is not limited to, tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2, 2″-dimethyl-biphenyl (CDBP), or 2-methyl-9,10-bis(naphthalen-2-yl)anthracene) (MADN).

In an example embodiment, each of the first light emitting material layer EML1, the second light emitting material layer EML2, and the third light emitting material layer EML3 may include a fluorescent material including any one of spiro-DPVBi, spiro-6P, distyryl-benzene (DSB), distyryl-arylene (DSA), a polyfluorene (PFO)-based polymer, or a poly (p-phenylene vinylene) (PPV)-based polymer. In an example embodiment, each of the first light emitting material layer EML1, the second light emitting material layer EML2, and the third light emitting material layer EML3 may include a phosphorescent material including an organometallic complex such as (4,6-F2ppy)2Irpic. The first light emitting material layer EML1, the second light emitting material layer EML2, and the third light emitting material layer EML3 may also include materials other than the above example materials.

As described above, at least one of the first light emitting material layer EML1, the second light emitting material layer EML2 or the third light emitting material layer EML3 and at least another one of the first light emitting material layer EML1, the second light emitting material layer EML2 or the third light emitting material layer EML3 emit blue light in different wavelength ranges. In an example embodiment, to emit blue light in different wavelength ranges, the first light emitting material layer EML1, the second light emitting material layer EML2 and the third light emitting material layer EML3 may include the same material, and a resonance distance may be adjusted. In some example embodiments, to emit blue light in different wavelength ranges, at least one of the first light emitting material layer EML1, the second light emitting material layer EML2 or the third light emitting material layer EML3 and at least another one of the first light emitting material layer EML1, the second light emitting material layer EML2 or the third light emitting material layer EML3 may include different materials.

However, example embodiments are not limited to the above examples. The first light emitting material layer EML1, the second light emitting material layer EML2 and the third light emitting material layer EML3 may all emit blue light having a peak wavelength of about 440 to about 480 nm and may include the same material.

In an example embodiment, at least any one of the first light emitting material layer EML1, the second light emitting material layer EML2 or the third light emitting material layer EML3 may emit the first blue light having the first peak wavelength, another one of the first light emitting material layer EML1, the second light emitting material layer EML2 or the third light emitting material layer EML3 may emit the second blue light having the second peak wavelength different from the first peak wavelength, and the other one of the first light emitting material layer EML1, the second light emitting material layer EML2 or the third light emitting material layer EML3 may emit third blue light having a third peak wavelength different from the first peak wavelength and the second peak wavelength.

In an example embodiment, any one of the first peak wavelength, the second peak wavelength or the third peak wavelength may be in the range between about 440 and 460 nm. Another one of the first peak wavelength, the second peak wavelength or the third peak wavelength may be in the range between about 460 and about 470 nm, and the other one of the first peak wavelength, the second peak wavelength or the third peak wavelength may be in the range between about 470 and about 480 nm.

In an example embodiment, the output light LE emitted from the light emitting layer OL may be blue light and may include a long wavelength component, a medium wavelength component and a short wavelength component. Therefore, the light emitting layer OL may emit blue light having a broader emission peak as the output light LE and may improve color visibility at a side viewing angle.

A light emitting element EL having the tandem structure has the advantage of improving light efficiency and/or the advantage of extending the life of the display device 1 as compared with a light emitting element having a non-tandem structure.

In an example embodiment, at least any one of the first light emitting material layer EML1, the second light emitting material layer EML2 or the third light emitting material layer EML3 may emit light of the third color, for example, blue light, and at least another one of the first light emitting material layer EML1, the second light emitting material layer EML2 or the third light emitting material layer EML3 may emit light of the second color, for example, green light. A peak wavelength of blue light emitted from at least any one of the first light emitting material layer EML1, the second light emitting material layer EML2, or the third light emitting material layer EML3 may be in the range between about 440 and about 480 nm or about 460 to about 480 nm. A peak wavelength of green light emitted from at least another one of the first light emitting material layer EML1, the second light emitting material layer EML2, or the third light emitting material layer EML3 may be in the range between about 510 and about 550 nm.

For example, any one of the first light emitting material layer EML1, the second light emitting material layer EML2 or the third light emitting material layer EML3 may be a green-light emitting layer which emits green light, and the other two of the first light emitting material layer EML1, the second light emitting material layer EML2 and the third light emitting material layer EML3 may be blue-light emitting layers which emit blue light. When the other two of the first light emitting material layer EML1, the second light emitting material layer EML2 and the third light emitting material layer EML3 are blue-light emitting layers, peak wavelengths of blue light emitted from the two blue-light emitting layers may be in the same range or in different ranges.

In an example embodiment, the output light LE emitted from the light emitting layer OL may be a mixture of the first component LE1 which is blue light and the second component LE2 which is green light. For example, when the first component LE1 is deep blue light and the second component LE2 is green light, the output light LE may be sky blue light. As in the above-described example embodiments, the output light LE emitted from the light emitting layer OL is a mixture of blue light and green light and includes a relatively-long wavelength component and a relatively-short wavelength component. Accordingly, the light emitting layer OL may emit blue light having a broader emission peak as the output light LE and may improve color visibility at a side viewing angle. In addition, when the second component LE2 of the output light LE is green light, a green light component of light provided from the display device 1 to the outside can be supplemented. Accordingly, the color reproducibility of the display device 1 can be improved.

In an example embodiment, a green-light emitting layer among the first light emitting material layer EML1, the second light emitting material layer EML2, and the third light emitting material layer EML3 may include a host and a dopant. The host of the green-light emitting layer may be, but is not limited to, tris(8-hydroxyquinolino)aluminum (Alq3), 4,4′-bis(N-carbazolyl)-1,1-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2″-dimethyl-biphenyl (CDBP), or 2-methyl-9,10-bis(naphthalen-2-yl)anthracene) (MADN). The dopant of the green-light emitting layer may be, but is not limited to, a fluorescent material including tris-(8-hydroyquinolato) aluminum(III) (Alq3) or a phosphorescent material such as Ir(ppy)3(fac tris(2-phenylpyridine)iridium), Ir(ppy)2(acac)(Bis(2-phenylpyridine) (acetylacetonate)iridium(III)) or Ir(mpyp)3(2-phenyl-4-methyl-pyridine iridium).

The first charge generation layer CGL1 may be located between the first stack STC1 and the second stack STC2. The first charge generation layer CGL1 may inject electric charges into each light emitting material layer. The first charge generation layer CGL1 may control a charge balance between the first stack STC1 and the second stack STC2. The first charge generation layer CGL1 may include an n-type charge generation layer CGL11 and a p-type charge generation layer CGL12. The p-type charge generation layer CGL12 may be placed on the n-type charge generation layer CGL11 and may be located between the n-type charge generation layer CGL11 and the second stack STC2.

The first charge generation layer CGL1 may have a structure in which the n-type charge generation layer CGL11 and the p-type charge generation layer CGL12 are in contact with each other. The n-type charge generation layer CGL11 may supply electrons to the first light emitting material layer EML1, and the p-type charge generation layer CGL12 may supply holes to the second light emitting material layer EML2. Because the first charge generation layer CGL1 is located between the first stack STC1 and the second stack STC2 to provide electric charges to the light emitting material layer of each stack, the luminous efficiency of the light emitting element EL can be improved, and a driving voltage can be lowered.

The first stack STC1 may be located on the first electrodes AE of the light emitting elements EL located in the emission areas EA. The first stack STC1 may further include a first hole transport layer HTL1, a first electron blocking layer BIL1, and a first electron transport layer ETL1.

The first hole transport layer HTL1 may be located on the first anodes AE of the light emitting elements EL. The first hole transport layer HTL1 may facilitate the transport of holes and may include a hole transport material. The hole transport material may include, but is not limited to, a carbazole derivative such as N-phenylcarbazole or polyvinylcarbazole; a fluorene derivative; a triphenylamine derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA); N,N′-di(1-naphthyl)-N,N′-diphenylbenzidine) (NPB); or 4,4′-Cyclohexylidene bis[N,N-bis(4-methylphenyl)benzenamine] (TAPC).

The first electron blocking layer BIL1 may be located on the first hole transport layer HTL1. For example, the first electron blocking layer BIL1 may be located between the first hole transport layer HTL1 and the first light emitting material layer EML1. The first electron blocking layer BIL1 may include a hole transport material and metal or a metal compound in order to reduce or prevent electrons generated by the first light emitting material layer EML1 from entering the first hole transport layer HTL1. In an example embodiment, the first hole transport layer HTL1 and the first electron blocking layer BIL1 may be formed as a single layer in which their respective materials are mixed.

The first electron transport layer ETL1 may be located on the first light emitting material layer EML1. For example, the first electron transport layer ETL1 may be located between the first charge generation layer CGL1 and the first light emitting material layer EML1. In an example embodiment, the first electron transport layer ETL1 may include an electron transport material such as tris-(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate) (Bebq2), 9,10-di(naphalene-2-yl)anthracene (ADN), or a mixture thereof. However, the electron transport material is not limited to the above examples.

The second stack STC2 may be located on the first charge generation layer CGL1. The second stack STC2 may further include a second hole transport layer HTL2, a second electron blocking layer BIL2, and a second electron transport layer ETL2.

The second hole transport layer HTL2 may be located on the first charge generation layer CGL1. The second hole transport layer HTL2 may include the same material as the first hole transport layer HTL1 or may include one or more materials selected from the materials included in the first hole transport layer HTL1. The second hole transport layer HTL2 may be composed of a single layer or multiple layers.

The second electron blocking layer BIL2 may be located on the second hole transport layer HTL2. For example, the second electron blocking layer BIL2 may be located between the second hole transport layer HTL2 and the second light emitting material layer EML2. The second electron blocking layer BIL2 may have the same material and structure as the first electron blocking layer BIL1 or may include one or more materials selected from the materials included in the first electron blocking layer BIL1.

The second electron transport layer ETL2 may be located on the second light emitting material layer EML2. For example, the second electron transport layer ETL2 may be located between the second charge generation layer CGL2 and the second light emitting material layer EML2. The second electron transport layer ETL2 may have the same material and structure as the first electron transport layer ETL1 or may include one or more materials selected from the materials included in the first electron transport layer ETL1. The second electron transport layer ETL2 may be composed of a single layer or multiple layers.

The second charge generation layer CGL2 may be located on the second stack STC2. For example, the second charge generation layer CGL2 may be located between the second stack STC2 and the third stack STC3. The second charge generation layer CGL2 may have the same structure as the first charge generation layer CGL1. For example, the second charge generation layer CGL2 may include an n-type charge generation layer CGL21 and a p-type charge generation layer CGL22. The p-type charge generation layer CGL22 may be located on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may include the same material or different materials.

The third stack STC3 may be located on the second charge generation layer CGL2. The third stack STC3 may further include a third hole transport layer HTL3 and a third electron transport layer ETL3.

The third hole transport layer HTL3 may be located on the second charge generation layer CGL2. The third hole transport layer HTL3 may include the same material as the first hole transport layer HTL1 or may include one or more materials selected from the materials included in the first hole transport layer HTL1. The third hole transport layer HTL3 may be composed of a single layer or multiple layers. When the third hole transport layer HTL3 is composed of multiple layers, the layers may include different materials.

The third electron transport layer ETL3 may be located on the third light emitting material layer EML3. For example, the third electron transport layer ETL3 may be located between the second electrode CE of the light emitting element EL and the third light emitting material layer EML3. The third electron transport layer ETL3 may have the same material and structure as the first electron transport layer ETL1 or may include one or more materials selected from the materials included in the first electron transport layer ETL1. The third electron transport layer ETL3 may be composed of a single layer or multiple layers. When the third electron transport layer ETL3 is composed of multiple layers, the layers may include different materials.

Although not illustrated in FIG. 6, a hole injection layer may be further located in at least any one of a space between the first electrode AE of each of the light emitting elements EL and the first stack STC1, a space between the first charge generation layer CGL1 and the second stack STC2, or a space between the second charge generation layer CGL2 and the third stack STC3. The hole injection layer may facilitate the injection of holes into the first light emitting material layer EML1, the second light emitting material layer EML2 and/or the third light emitting material layer EML3. In an example embodiment, the hole injection layer may include, but not limited to, any one or more of copper phthalocyanine (CuPc), poly(3,4-ethylenedioxythiphene) (PEDOT), polyaniline (PANI), or N,N-dinaphthyl-N,N′-diphenyl benzidine (NPD).

In addition, an electron injection layer may be further located in at least any one of a space between the first stack STC1 and the first charge generation layer CGL1, a space between the second stack STC2 and the second charge generation layer CGL2, or a space between the third electron transport layer ETL3 and the second electrode CE of the light emitting elements EL. The electron injection layer may facilitate the injection of electrons and may use, but is not limited to, tris(8-hydroxyquinolino)aluminum) (Alq3), PBD, TAZ, spiro-PBD, BAlq or SAlq. In addition, the electron injection layer may be a metal halide compound, for example, may be, but is not limited to, any one or more of MgF₂, LiF, NaF, KF, RbF, CsF, FrF, LiI, NaI, KI, RbI, CsI, FrI or CaF₂. The electron injection layer may also include a lanthanum material such as Yb, Sm, or Eu. In some example embodiments, the electron injection layer may include both a metal halide material and a lanthanum material, such as RbI:Yb or KI:Yb. When the electron injection layer includes both a metal halide material and a lanthanum material, the electron injection layer may be formed by co-deposition of the metal halide material and the lanthanum material.

In an example embodiment, the light emitting layer OL may not include a red-light emitting material layer and thus may not emit red light. For example, the output light LE may not include a light component having a peak wavelength of about 610 to about 650 nm and may include only a light component having a peak wavelength of about 440 to about 550 nm.

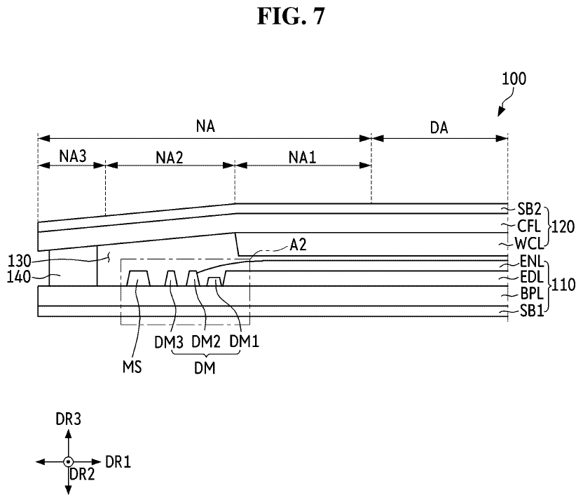

FIG. 7 is a cross-sectional view of the display panel 100 according to an example embodiment. For example, FIG. 7 schematically shows a cross-section of a portion of the display panel 100, which includes a portion of the non-display area NA located at an edge (e.g., a left edge) of the display panel 100 and a portion of the display area DA adjacent to the portion of the non-display area NA.

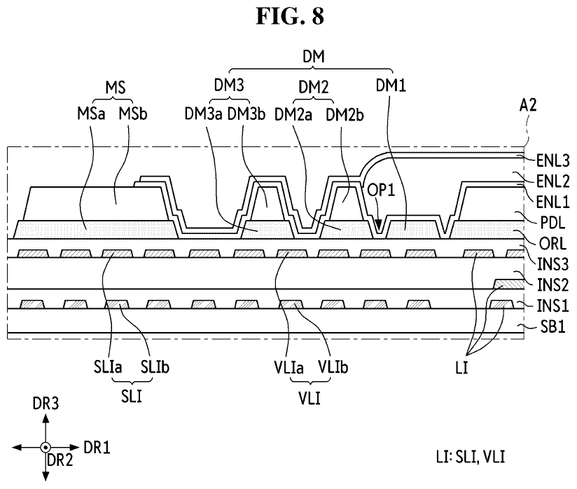

FIG. 8 is an enlarged view of area A2 of FIG. 7. For example, FIG. 8 shows, in detail, a dam structure DM and an organic structure MS according to an example embodiment, and wirings LI located under the dam structure DM and the organic structure MS.

Referring to FIGS. 7 and 8 in addition to FIGS. 1 through 6, the display panel 100 may further include a sealant 140 located in the non-display area DA. The sealant 140 may be located outside the dam structure DM and the organic structure MS.

The sealant 140 may include a material suitable for bonding a lower panel 110 and an upper panel 120 of the display panel 100 and protecting elements inside the display panel 100. In an example embodiment, the sealant 140 may include a light transmitting material and may be cured through photocuring.

The non-display area NA may include a first non-display area NA1, a second non-display area NA2, and a third non-display area NA3 which are gradually further away from the display area DA. For example, the first non-display area NA1 may be immediately adjacent to the display area DA, the second non-display area NA2 may be located outside the first non-display area NA1, and the third non-display area NA3 may be located outside the second non-display area NA2. For example, in the first direction DR1, the first non-display area NA1 may be located on left and right sides of the display area DA, the second non-display area NA2 may be located on left and right sides of the first non-display area NA1, and the third non-display area NA3 may be located on left and right sides of the second non-display area NA2. In an example embodiment, the first non-display area NA1 may surround the display area DA, the second non-display area NA2 may surround the first non-display area NA1, and the third non-display area NA3 may surround the second non-display area NA2.

The first substrate SB1, the backplane layer BPL, and the second substrate SB2 may be entirely located in the display area DA and the non-display area NA. For example, the first substrate SB1, the backplane layer BPL, and the second substrate SB2 may be located in the display area DA, the first non-display area NA1, the second non-display area NA2, and the third non-display area NA3. In an example embodiment, the color filter layer CFL may also be entirely located in the display area DA and the non-display area NA. For example, the color filter layer CFL may be located in the display area DA, the first non-display area NA1, the second non-display area NA2, and the third non-display area NA3.

The first substrate SB1 may have an overall uniform thickness and may be substantially flat. For example, the first substrate SB1 may have an overall uniform thickness across the display area DA and the non-display area NA and may be flat. However, the shape or size of the first substrate SB1 may vary depending on example embodiments.

The backplane layer BPL may include circuit elements located in the display area DA. For example, the backplane layer BPL may include the transistors T and the capacitors Cst of the pixels PX located in the display area DA.

In an example embodiment, the backplane layer BPL may further include circuit elements located in the non-display area NA. For example, the backplane layer BPL may further include circuit elements of the gate drivers GD (e.g., transistors and capacitors of the stages ST) located in the non-display area NA. In an example embodiment, the circuit elements of the gate drivers GD may be located or formed in the backplane layer BPL in the first non-display area NA1.

The backplane layer BPL may further include wirings LI located in the display area DA and the non-display area NA. As an example of the wirings LI that may be included in the backplane layer BPL, FIG. 8 schematically shows an example of the wirings LI that may be located in the non-display area NA of the backplane layer BPL.

In an example embodiment, the wirings LI of the backplane layer BPL may include signal lines SLI and driving voltage lines VLI which are electrically connected to the gate drivers GD. In an example embodiment, the gate drivers GD may be located in the first non-display area NA1, and at least some of the signal lines SLI and the driving voltage lines VLI may be located in the second non-display area NA2. For example, at least one of the signal lines SLI may be located under the organic structure MS, and at least one of the driving voltage lines VLI may be located under the dam structure DM.

The wirings LI may be formed as patterns included in at least one of the conductive layers (e.g., the first conductive layer CDL1, the second conductive layer CDL2, and the third conductive layer CDL3 of FIG. 5) included in the backplane layer BPL. In addition, each of the wirings LI may have a single-layer or multilayer structure. The wirings LI may be covered with at least one insulating layer, for example, the third insulating layer INS3.

In an example embodiment, each of the signal lines SLI (or at least one of the signal lines SLI) may include a main wiring layer SLIa formed as a pattern of the third conductive layer CDL3 including the source electrode SE and/or the drain electrode DE of FIG. 5. In an example embodiment, each of the signal lines SLI may be formed as a multilayer wiring including another wiring layer in addition to the main wiring layer SLIa. For example, each of the signal lines SLI may further include a sub-wiring layer SLIb formed as a pattern of the first conductive layer CDL1 including the bottom electrode BE of FIG. 5, and the main wiring layer SLIa and the sub-wiring layer SLIb of each of the signal lines SLI may be electrically connected to each other through a contact hole or the like in an area not illustrated.

In an example embodiment, each of the driving voltage lines VLI (or at least one of the driving voltage lines VLI) may include a main wiring layer VLIa formed as a pattern of the third conductive layer CDL3. In an example embodiment, each of the driving voltage lines VLI may be formed as a multilayer wiring including another wiring layer in addition to the main wiring layer VLIa. For example, each of the driving voltage lines VLI may further include a sub-wiring layer VLIb formed as a pattern of the first conductive layer CDL1, and the main wiring layer VLIa and the sub-wiring layer VLIb of each of the driving voltage lines VLI may be electrically connected to each other through a contact hole or the like in an area not illustrated.

Each of the wirings LI other than the signal lines SLI and the driving voltage lines VLI may include at least one wiring layer included in at least one of the conductive layers of the backplane layer BPL. For example, each of the wirings LI may include at least one wiring layer included in the first conductive layer CDL1, the second conductive layer CDL2, and/or the third conductive layer CDL3 of the backplane layer BPL.

The second substrate SB2 may be flat overall or may have an inclined surface or a curved surface. For example, the second substrate SB2 may be substantially flat in the display area DA and may have a slope, which becomes closer to the first substrate SB1 toward the periphery, in the non-display area NA. However, the shape and size of the second substrate SB2 may vary depending on example embodiments.

The color filter layer CFL may be entirely located over the display area DA and the non-display area NA. However, color filters of the color filter layer CFL may be placed in different shapes in the display area DA and the non-display area NA. For example, as illustrated in FIG. 5, only one color filter which selectively transmits light corresponding to the emission wavelength of a corresponding pixel PX may be located in the emission area EA of each pixel PX. In addition, the first color filter CF1, the second color filter CF2 and the third color filter CF3 may overlap each other in the non-emission area NEA and the non-display area NA to form a light blocking pattern.

The light emitting element layer EDL, the encapsulation layer ENL, and the wavelength conversion layer WCL may be located only on a portion of the first substrate SB1 and/or the second substrate SB2. For example, the light emitting element layer EDL, the encapsulation layer ENL, and the wavelength conversion layer WCL may be located in the display area DA and the first non-display area NA1. In an example embodiment, ends of the light emitting element layer EDL and the encapsulation layer ENL may be located in the second non-display area NA2, and some elements (or some portions) of the light emitting element layer EDL and the encapsulation layer ENL may be located in the second non-display area NA2.

The light emitting element layer EDL may include the light emitting elements EL located in the display area DA. For example, the light emitting element layer EDL may include a light emitting element EL located in the emission area EA of each pixel PX. In an example embodiment, the light emitting layer OL and the second electrode CE of the light emitting elements EL may be formed in the entire display area DA and may end in the non-display area NA. In an example embodiment, the second electrode CE may have a larger area than the light emitting layer OL and may completely cover the light emitting layer OL. For example, in the non-display area NA, an end of the second electrode CE may be located outside an end of the light emitting layer OL.

In an example embodiment, the display panel 100 may further include a dummy pixel located in the first non-display area NA1, and the light emitting element layer EDL may include a dummy light emitting element located in the dummy pixel. The dummy pixel may further include a dummy pixel circuit connected to the dummy light emitting element. The dummy pixel circuit may include circuit elements located in the first non-display area NA1. The dummy pixel may be located between the display area DA and the gate drivers GD. In some example embodiments, the dummy pixel may be omitted.

The encapsulation layer ENL may be entirely located in the display area DA and the first non-display area NA1 and may end in the second non-display area NA2. For example, the second encapsulation layer ENL2 including an organic material may be formed within an area limited by the dam structure DM. For example, a range in which the organic material of the second encapsulation layer ENL2 diffuses may be limited by the dam structure DM. The first encapsulation layer ENL1 and the third encapsulation layer ENL3 may extend further outward than the second encapsulation layer ENL2, and ends of the first encapsulation layer ENL1 and the third encapsulation layer ENL3 may be bonded together outside an end of the second encapsulation layer ENL2. In an example embodiment, the first encapsulation layer ENL1 and the third encapsulation layer ENL3 may end on the organic structure MS, but example embodiments are not limited to this case.

The wavelength conversion layer WCL may be located in the entire display area DA and may end in the first non-display area NA1 or the second non-display area NA2. The wavelength conversion patterns WCP of the wavelength conversion layer WCL may be located in the emission areas EA of the pixels PX. The bank BNK of the wavelength conversion layer WCL may be located in the non-emission area NEA of the display area DA and the non-display area NA. In an example embodiment, the wavelength conversion layer WCL may further include a dummy wavelength conversion pattern located on the dummy light emitting element in the first non-display area NA1, but example embodiments are not limited to this case.

The dam structure DM and the organic structure MS may be sequentially placed in the second non-display area NA2. For example, the dam structure DM may be located in a portion of the second non-display area NA2 which is adjacent to the first non-display area NA1, and the organic structure MS may be located in another portion of the second non-display area NA2 which is adjacent to the third non-display area NA3.

The dam structure DM may include at least one dam. For example, the dam structure DM may include a first dam DM1 surrounding the display area DA, a second dam DM2 surrounding the first dam DM1, and a third dam DM3 surrounding the second dam DM2.

Each dam may have a single-layer or multilayer structure. In an example embodiment, each dam may include a single-layer or multilayer organic insulating layer including an organic material. For example, each dam may be formed at the same time as at least one organic insulating layer included in the backplane layer BPL and/or the light emitting diode layer EDL and including an organic material. Therefore, each dam may include the same material as the at least one insulating layer.

In an example embodiment, the first dam DM1 may be formed at the same time as the organic layer ORL of the display area DA and may include the same material as the organic layer ORL. Each of the second dam DM2 and the third dam DM3 may include a first layer DM2a or DM3a formed at the same time as the organic layer ORL and including the same material as the organic layer ORL and a second layer DM2b or DM3b formed at the same time as the pixel defining layer PDL of the display area DA and including the same material as the pixel defining layer PDL. The second layers DM2b and DM3b of the second dam DM2 and the third dam DM3 may be located on the first layers DM2a and DM3a of the second dam DM2 and the third dam DM3, respectively.

The first dam DM1, the second dam DM2, and the third dam DM3 may be separated and/or spaced apart from each other. For example, the first layer DM2a of the second dam DM2 may be spaced apart from the first dam DM1 with an opening OP1. The opening OP1 may be located between the first layer DM2a of the second dam DM2 and the first dam DM1.

The dam structure DM may overlap at least one wiring LI located in the second non-display area NA2. For example, the dam structure DM may overlap a plurality of driving voltage lines VLI arranged in the first direction DR1 in the second non-display area NA2 and extending in the second direction DR2.

The organic structure MS may have a single-layer or multilayer structure. In an example embodiment, the organic structure MS may have a multilayer structure including a first organic layer MSa and a second organic layer MSb. Accordingly, the organic structure MS may appropriately or effectively support a mask which is utilized in each process for forming the light emitting elements EL, the encapsulation layer ENL, etc. The mask used in the process of forming the lower panel 110 of the display panel 100 may be bonded only to the organic structure MS on the backplane layer BPL of the display panel 100 and may be spaced apart from other parts of the display panel 100 being manufactured.

In an example embodiment, the first organic layer MSa may be formed at the same time as the organic layer ORL of the display area DA and may include the same material as the organic layer ORL. The second organic layer MSb may be formed at the same time as the pixel defining layer PDL and may include the same material as the pixel defining layer PDL.

In an example embodiment, the organic structure MS may be utilized as a mask support in the process of forming the light emitting elements EL and the encapsulation layer ENL. For example, the organic structure MS may be utilized as a mask support in each process for forming the light emitting layer OL and the second electrode CE of the light emitting elements EL, the first encapsulation layer ENL1, and the third encapsulation layer ENL3.

For example, a mask used in the process of forming the light emitting layer OL of the light emitting elements EL may have an opening corresponding to an area where the light emitting layer OL is to be formed. In addition, the mask may have a frame surrounding the opening, and the frame may be mounted on the organic structure MS. The light emitting layer OL may be formed in the area corresponding to the opening of the mask.

Similarly, a mask used in the process of forming the second electrode CE of the light emitting elements EL may have an opening corresponding to an area where the second electrode CE is to be formed. In addition, the mask may have a frame surrounding the opening, and the frame may be mounted on the organic structure MS. The second electrode CE may be formed in the area corresponding to the opening of the mask.

In addition, a mask used in the process of forming the first encapsulation layer ENL1 and the third encapsulation layer ENL3 may have an opening corresponding to an area where the first encapsulation layer ENL1 and the third encapsulation layer ENL3 are to be formed. In addition, the mask may have a frame surrounding the opening, and the frame may be mounted on the organic structure MS. The first encapsulation layer ENL1 and the third encapsulation layer ENL3 may be formed in the area corresponding to the opening of the mask.

In an example embodiment, the frame of each mask may include a bonding portion which protrudes downward in a size, shape, and/or position corresponding to those of the organic structure MS. Accordingly, the frame can be more stably attached onto the organic structure MS, and thus the mask can be stably supported by the organic structure MS.

The organic structure MS may overlap at least one wiring LI located in the second non-display area NA2. For example, the organic structure MS may have a width sufficient to stably support a mask used in the process of manufacturing the display panel 100. Accordingly, the organic structure MS may overlap a plurality of signal lines SLI sequentially arranged (e.g., arranged in series) in the first direction DR1. In an example embodiment, the signal lines SLI overlapping the organic structure MS may be clock signal lines to which clock signals CK having different waveforms and/or phases are applied.

In the case of the display panel 100 including the lower panel 110 and the upper panel 120 as in the above-described example embodiment, an inorganic layer, etc. inside the display panel 100 may be damaged or deformed in the process of manufacturing the display panel 100. For example, peeling between color filters may occur within the color filter layer CFL due to stress applied in the process of bonding the lower panel 110 and the upper panel 120 or that at least one inorganic layer included in the lower panel 110 and/or the upper panel 120 of the display panel 100 may be damaged by a spacer or the like inside the sealant 140. When such damage or deformation occurs, the inside of the display panel 100 may not be completely sealed, and a path through which outside air can penetrate into the display panel 100 may be created. The outside air that has penetrated into the display panel 100 may be adsorbed onto a portion where an organic layer is exposed without being covered by inorganic encapsulation layers (e.g., the first encapsulation layer ENL1 and the third encapsulation layer ENL3) of the encapsulation layer ENL, for example, may be adsorbed onto the organic structure MS. When the outside air is absorbed onto the organic structure MS, a dielectric constant of the organic structure MS may change, causing a difference in resistive-capacitive (RC) delay between the wirings LI under the organic structure MS (e.g., the signal lines SLI overlapping the organic structure MS) and other wirings LI. The difference in RC delay between the wirings LI may cause a difference between gate signals (e.g., the scan signals SC) output from the gate drivers GD, which may cause image quality defects of the display device 1 (e.g., horizontal line defects in which horizontal line-shaped stains are visible on an image).

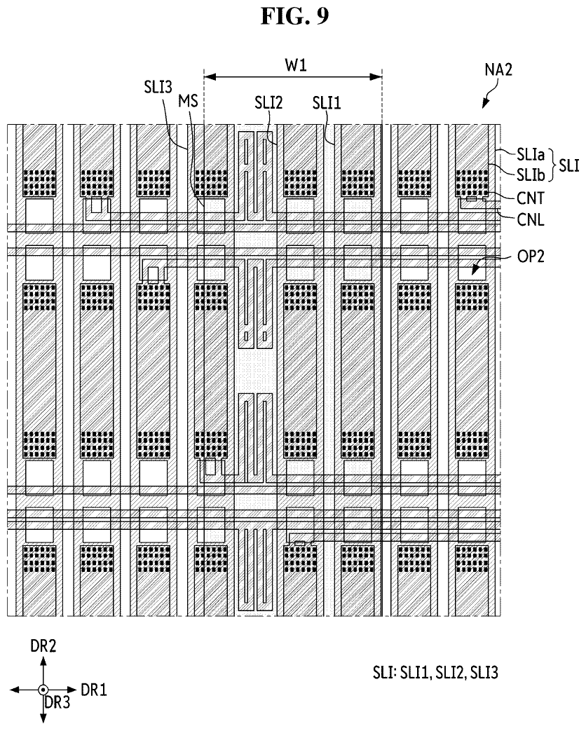

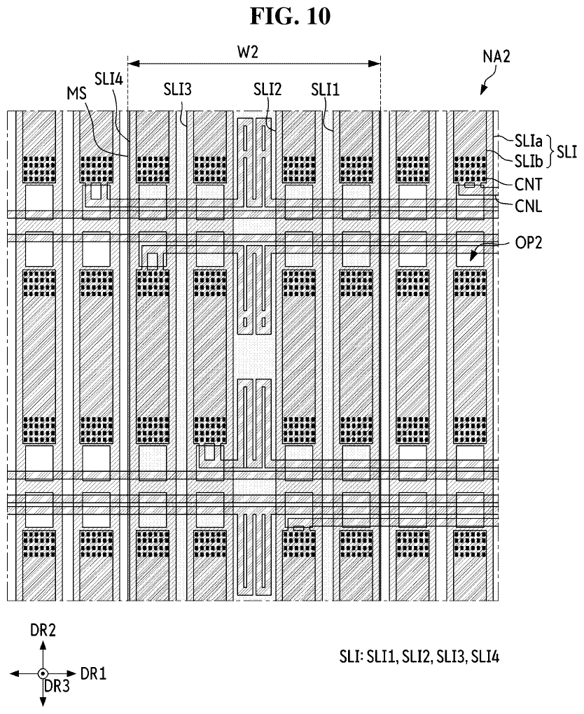

FIG. 9 is a plan view illustrating signal lines and an organic structure according to an example embodiment. FIG. 10 is a plan view illustrating signal lines and an organic structure according to an example embodiment. For example, FIGS. 9 and 10 show part of signal lines SLI and an organic structure MS located in the second non-display area NA2 and show different example embodiments in relation to a width of the organic structure MS.

Referring to FIGS. 9 and 10 in addition to FIGS. 1 through 8, a plurality of signal lines SLI may be arranged in the first direction DR1 in the second non-display area NA2. Each of the signal lines SLI may extend substantially in the second direction DR2.

In an example embodiment, each of the signal lines SLI may include a main wiring layer SLIa and a sub-wiring layer SLIb. The main wiring layer SLIa and the sub-wiring layer SLIb may overlap each other in the third direction DR3. In an example embodiment, the main wiring layer SLIa may be formed as a pattern of the third conductive layer CDL3, and the sub-wiring layer SLIb may be formed as a pattern of the first conductive layer CDL1 and located under a portion of the main wiring layer SLIa. The main wiring layer SLIa and the sub-wiring layer SLIb may be electrically connected to each other through a plurality of contact holes CNT.

Each of the signal lines SLI may be electrically connected to at least one stage ST included in a gate driver GD through a connection line CNL. Each connection line CNL may extend generally in the first direction DR1.

In an example embodiment, the connection lines CNL may be formed as patterns of the first conductive layer CDL1, and the sub-wiring layer SLIb of each of the signal lines SLI may be discontinuous in the second direction DR2. For example, the sub-wiring layer SLIb of each of the signal lines SLI may be composed of conductive patterns separated from each other in the second direction DR2, and the connection lines CNL may pass between the conductive patterns of the sub-wiring layer SLIb. A connection line CNL connected to each signal line SLI may be formed integrally with the sub-wiring layer SLIb of the corresponding signal line SLI.

In an example embodiment, at least one connection line CNL may include a bend (e.g., a curved portion) for load matching of the signal lines SLI. In an example embodiment, a plurality of connection lines CNL may include respective bends located between two signal lines SLI adjacent to each other in the first direction DR1.

In an example embodiment, the main wiring layer SLIa of each of the signal lines SLI may include at least one opening OP2 formed in an area where the connection lines CNL are located. Accordingly, parasitic capacitance formed between the signal lines SLI and the connection lines CNL can be reduced, and driving signals (e.g., clock signals input to the stages ST) can be stably supplied to the gate driver GD.

The organic structure MS may have a width greater than a width of each of the signal lines SLI and may overlap a plurality of signal lines SLI adjacent to each other in the first direction DR1. In an example embodiment, as illustrated in FIG. 9, the organic structure MS may overlap a first signal line SLI1, a second signal line SLI2, and a third signal line SLI3 sequentially arranged (e.g., arranged in series) in the first direction DR1. In addition, the organic structure MS may have a first width W1 greater than a width of each of the first signal line SLI1, the second signal line SLI2, and the third signal line SLI3 in the first direction DR1. In an example embodiment, as illustrated in FIG. 10, the organic structure MS may overlap a first signal line SLI1, a second signal line SLI2, a third signal line SLI3, and a fourth signal line SLI4 sequentially arranged (e.g., arranged in series) in the first direction DR1. In addition, the organic structure MS may have a second width W2 greater than the first width W1 in the first direction DR1. The width of the organic structure MS and/or the number of signal lines SLI overlapping the organic structure MS may vary depending on example embodiments.

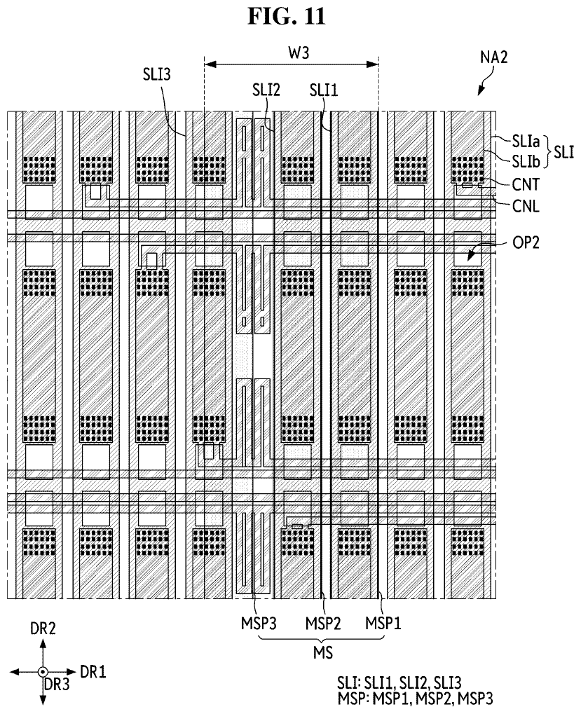

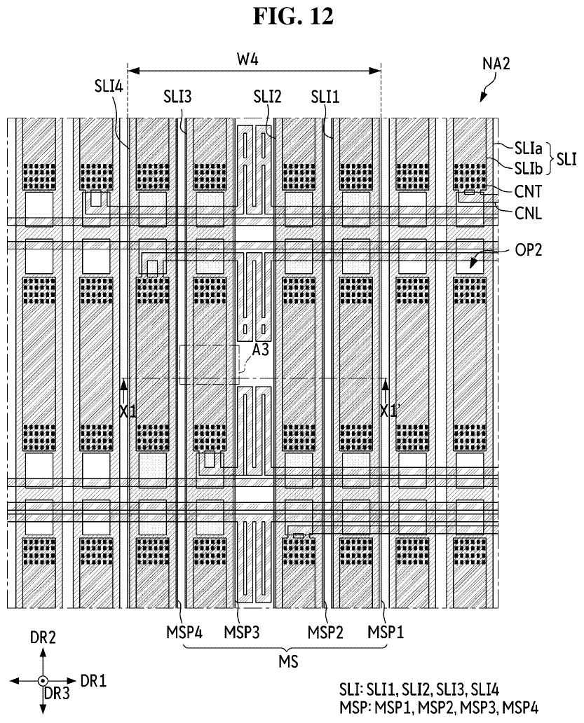

FIG. 11 is a plan view illustrating signal lines and an organic structure according to an example embodiment. FIG. 12 is a plan view illustrating signal lines and an organic structure according to an example embodiment. For example, FIGS. 11 and 12 show part of signal lines SLI and an organic structure MS located in the second non-display area NA2 and show different example embodiments from the example embodiments of FIGS. 9 and 10 in relation to the organic structure MS. In the description of the example embodiments of FIGS. 11 and 12, elements similar or identical to those of the above-described example embodiments are indicated by like reference characters, and a redundant description thereof will be omitted.

Referring to FIGS. 11 and 12 in addition to FIGS. 7 through 10, the organic structure MS may overlap a plurality of signal lines SLI and may be divided into shapes corresponding to the signal lines SLI. For example, the organic structure MS may be divided into division patterns MSP in a shape corresponding to that of each signal line SLI located under the organic structure MS. For example, the division patterns MSP of the organic structure MS may overlap different signal lines SLI among the signal lines SLI and may be spaced apart from each other at least in the first direction DR1. The organic structure MS may include a number of division patterns MSP corresponding to the number of signal lines SLI located in an area where the organic structure MS is located. Each division pattern MSP may have a width similar to a width of each signal line SLI.

In an example embodiment, when the organic structure MS overlaps a first signal line SLI1, a second signal line SLI2 and a third signal line SLI3 and has a third width W3 in the first direction DR1 as illustrated in FIG. 11, the organic structure MS may include a first division pattern MSP1 located on the first signal line SLI1, a second division pattern MSP2 located on the second signal line SLI2, and a third division pattern MSP3 located on the third signal line SLI3. The first division pattern MSP1, the second division pattern MSP2, and the third division pattern MSP3 may be separated and/or spaced apart from each other at least in the first direction DR1. The third width W3 of the organic structure MS according to the example embodiment of FIG. 11 may be equal or similar to the first width W1 of the organic structure MS according to the example embodiment of FIG. 9. For example, it is possible to divide the organic structure MS into shapes corresponding to the signal lines SLI under the organic structure MS while maintaining or securing the width of the organic structure MS sufficient to stably support a mask, etc.

Each division pattern MSP may overlap only a signal line SLI to which one signal is applied. For example, the first signal line SLI1, the second signal line SLI2, and the third signal line SLI3 may be clock signal lines to which a first clock signal, a second clock signal, and a third clock signal having different phases and/or waveforms are applied, respectively. In this case, the first division pattern MSP1 may cover at least a portion of the first signal line SLI1, but may not be located on the second signal line SLI2 and the third signal line SLI3. In addition, the second division pattern MSP2 may cover at least a portion of the second signal line SLI2, but may not be located on the first signal line SLI1 and the third signal line SLI3, and the third division pattern MSP3 may cover at least a portion of the third signal line SLI3, but may not be located on the first signal line SLI1 and the second signal line SLI2.

In an example embodiment, when the organic structure MS overlaps a first signal line SLI1, a second signal line SLI2, a third signal line SLI3 and a fourth signal line SLI4 and has a fourth width W4 in the first direction DR1 as illustrated in FIG. 12, the organic structure MS may include a first division pattern MSP1 located on the first signal line SLI1, a second division pattern MSP2 located on the second signal line SLI2, a third division pattern MSP3 located on the third signal line SLI3, and a fourth division pattern MSP4 located on the fourth signal line SLI4. The first division pattern MSP1, the second division pattern MSP2, the third division pattern MSP3, and the fourth division pattern MSP4 may be separated and/or spaced apart from each other at least in the first direction DR1. The fourth width W4 of the organic structure MS according to the example embodiment of FIG. 12 may be equal or similar to the second width W2 of the organic structure MS according to the example embodiment of FIG. 10.

Each division pattern MSP may overlap only a signal line SLI to which one signal is applied. For example, when a first clock signal, a second clock signal, a third clock signal and a fourth clock signal having different phases and/or waveforms are applied to the first signal line SLI1, the second signal line SLI2, the third signal line SLI3 and the fourth signal line SLI4, the first division pattern MSP1 may cover at least a portion of the first signal line SLI1, but may not be located on the second signal line SLI2, the third signal line SLI3 and the fourth signal line SLI4. The second division pattern MSP2 may cover at least a portion of the second signal line SLI2, but may not be located on the first signal line SLI1, the third signal line SLI3 and the fourth signal line SLI4. The third division pattern MSP3 may cover at least a portion of the third signal line SLI3, but may not be located on the first signal line SLI1, the second signal line SLI2 and the fourth signal line SLI4. The fourth division pattern MSP4 may cover at least a portion of the fourth signal line SLI4, but may not be located on the first signal line SLI1, the second signal line SLI2 and the third signal line SLI3.

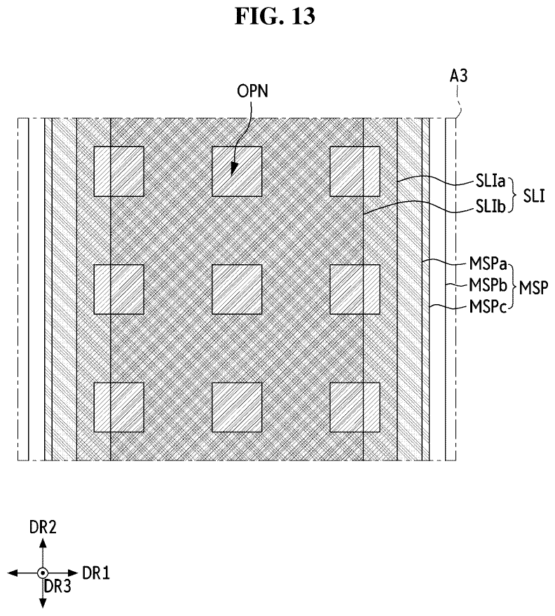

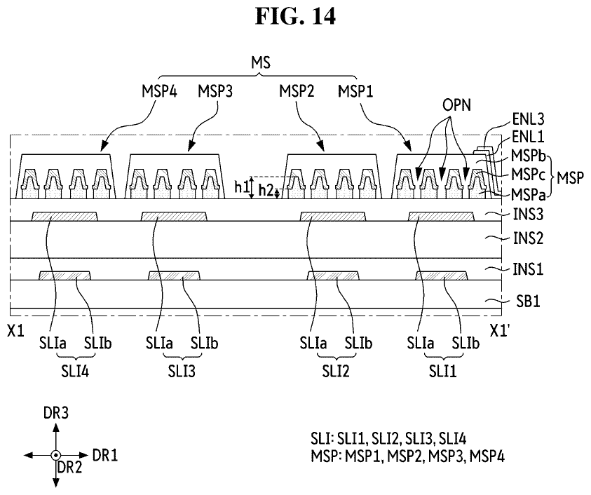

FIG. 13 is an enlarged view of area A3 of FIG. 12 according to an example embodiment. For example, FIG. 13 shows, in detail, a division pattern MSP (e.g., a portion of a third division pattern MSP3) included in an organic structure MS according to an example embodiment. FIG. 14 shows an example embodiment of cross-sections of signal lines and an organic structure taken along line X1-X1′ of FIG. 12.

Referring to FIGS. 13 and 14 in addition to FIGS. 1 through 12, each division pattern MSP of the organic structure MS according to the example embodiment may include a first organic pattern MSPa located on a signal line SLI. In an example embodiment, the first organic pattern MSPa may be formed at the same time as the organic layer ORL of the display area DA and may include the same material as the organic layer ORL. In an example embodiment, the first organic pattern MSPa may have a width greater than a width of the signal line SLI and may completely cover an upper surface of the signal line SLI, but example embodiments are not limited to this case.

The first organic patterns MSPa of the division patterns MSP included in the organic structure MS may be spaced apart and/or separated from each other in the first direction DR1. The first organic patterns MSPa of the division patterns MSP may form a first organic layer MSa of the organic structure MS.

The first organic patterns MSPa may have different heights or thicknesses in different portions. For example, the first organic patterns MSPa may have a first height h1 (or a first thickness) under a central portion of each of inorganic patterns MSPc and may have a second height h2 (or a second thickness smaller than the first thickness), which is lower than the first height h1, under both ends of each of the inorganic patterns MSPc.

In an example embodiment, each division pattern MSP may further include a second organic pattern MSPb located on a first organic pattern MSPa. In an example embodiment, the second organic pattern MSPb may be formed at the same time as the pixel defining layer PDL of the display area DA and may include the same material as the pixel defining layer PDL. In an example embodiment, the second organic pattern MSPb may have a width greater than the width of the first organic pattern MSPa and may cover upper and side surfaces of the first organic pattern MSPa, but example embodiments are not limited to this case.

The second organic patterns MSPb of the division patterns MSP included in the organic structure MS may be spaced apart and/or separated from each other in the first direction DR1. The second organic patterns MSPb of the division patterns MSP may form a second organic layer MSb of the organic structure MS.

In an example embodiment, each division pattern MSP may further include an inorganic pattern MSPc located on a first organic pattern MSPa. For example, the inorganic pattern MSPc may be located between the first organic pattern MSPa and a second organic pattern MSPb and may cover the upper surface of the first organic pattern MSPa. The second organic pattern MSPb may be located on the first organic pattern MSPa and the inorganic pattern MSPc.

In an example embodiment, the inorganic pattern MSPc may be formed at the same time as the first electrode AE of each of the light emitting elements EL and may include the same material as the first electrode AE. A width of the inorganic pattern MSPc and the width of the first organic pattern MSPa may be substantially equal or similar to each other. For example, the inorganic pattern MSPc may have a width equal to or greater than the width of the first organic pattern MSPa and may cover the upper surface of the first organic pattern MSPa, but example embodiments are not limited to this case.

The inorganic patterns MSPc of the division patterns MSP included in the organic structure MS may be spaced apart and/or separated from each other in the first direction DR1. The inorganic patterns MSPc of the division patterns MSP may function as a capping layer which covers the first organic layer MSa of the organic structure MS.

In an example embodiment, the inorganic patterns MSPc may include a plurality of openings OPN for outgassing. For example, gas generated from the first organic patterns MSPa in the process of manufacturing the display panel 100 may be appropriately released out of the organic structure MS through the openings OPN of the inorganic patterns MSPc. Accordingly, reliability of the display device 1 can be improved or secured.

In an example embodiment, the first organic patterns MSPa may be formed by utilizing the inorganic patterns MSPc as a mask. Accordingly, the first organic patterns MSPa may have a shape corresponding to that of the inorganic patterns MSPc. For example, the first organic patterns MSPa and the inorganic patterns MSPc may include openings OPN having substantially the same shape and/or size.

In an example embodiment, when the encapsulation layer ENL ends in an area where the organic structure MS is located as in the example embodiment of FIG. 8, ends of the first encapsulation layer ENL1 and the third encapsulation layer ENL3 may be located on one (e.g., the first division pattern MSP1 closest to the display area DA) of the division patterns MSP of the organic structure MS. However, example embodiments are not limited to this case. For example, the ends of the first encapsulation layer ENL1 and the third encapsulation layer ENL3 may also be located on the dam structure DM.

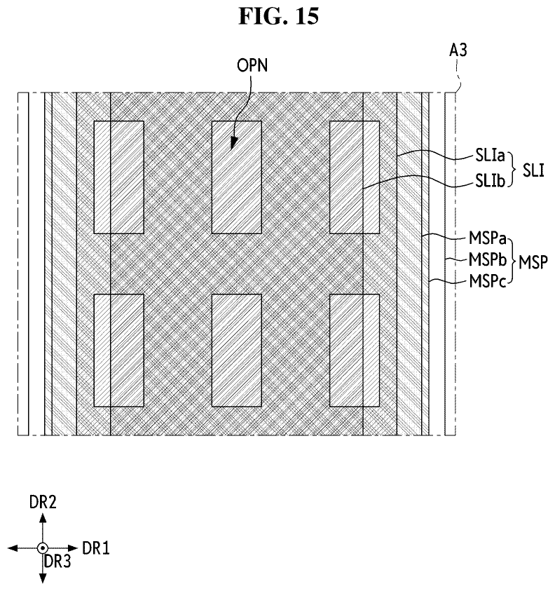

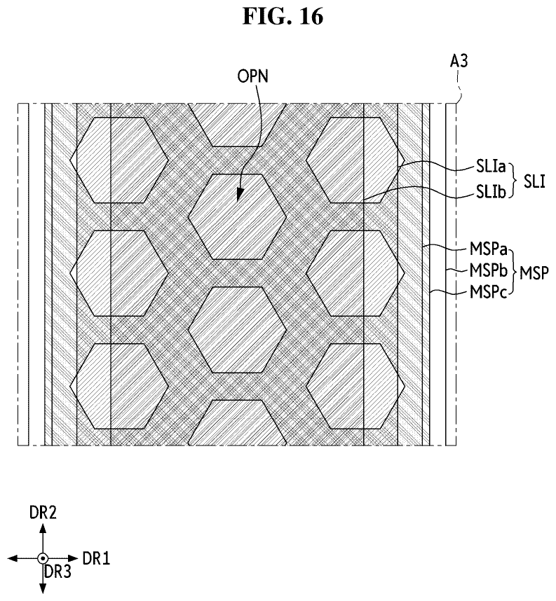

FIG. 15 is an enlarged view of area A3 of FIG. 12 according to an example embodiment. FIG. 16 is an enlarged view of area A3 of FIG. 12 according to an example embodiment. For example, FIGS. 15 and 16 each show, in detail, a division pattern MSP MS (e.g., a portion of a third division pattern MSP3) included in an organic structure according to an example embodiment. FIGS. 15 and 16 show some example embodiments different from the example embodiment of FIG. 13 in relation to openings OPN formed in a first organic pattern MSPa and an inorganic pattern MSPc.

Referring to FIGS. 15 and 16 in addition to FIGS. 13 and 14, the shape of the openings OPN formed in the first organic pattern MSPa and the inorganic pattern MSPc may be variously changed. For example, the openings OPN of the first organic pattern MSPa and the inorganic pattern MSPc may have a square planar shape as illustrated in FIG. 13, a rectangular planar shape as illustrated in FIG. 15, or a hexagonal planar shape as illustrated in FIG. 16. In addition to the shapes illustrated in FIGS. 13 through 16, the shape, size, number, and/or arrangement structure of the openings OPN formed in the first organic pattern MSPa and the inorganic pattern MSPc may be variously changed according to example embodiments.

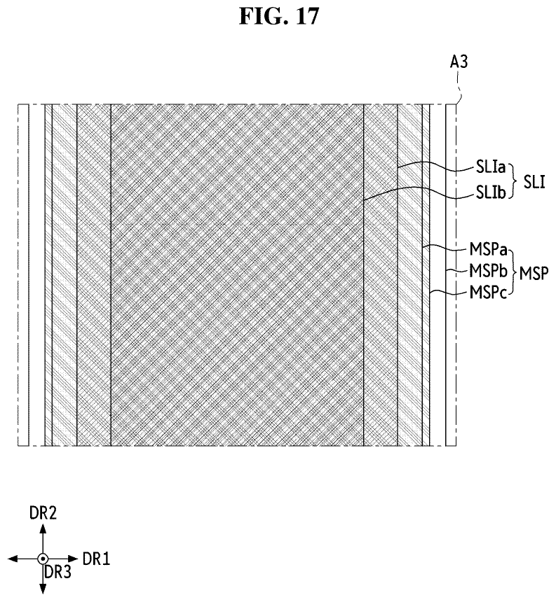

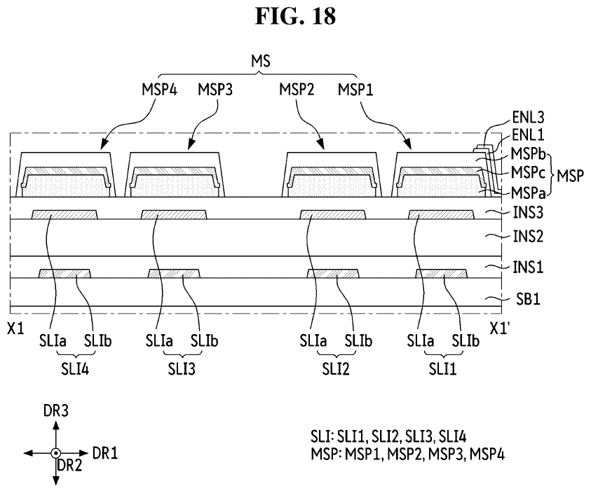

FIG. 17 is an enlarged view of area A3 of FIG. 12 according to an example embodiment. For example, FIG. 17 shows, in detail, a division pattern MSP (e.g., a portion of a third division pattern MSP3) included in an organic structure MS according to an embodiment. FIG. 18 shows a cross-sectional view of signal lines and an organic structure taken along line X1-X1′ of FIG. 12 according to an example embodiment. FIGS. 17 and 18 show embodiments different from the embodiments of FIGS. 13 and 14 in relation to a first organic pattern MSPa and an inorganic pattern MSPc.

Referring to FIGS. 17 and 18 in addition to FIGS. 13 through 16, at least one pattern MSP may not include the openings OPN described in the example embodiments of FIGS. 13 through 16. For example, in case that signal lines SLI have a narrow width, division patterns MSP, into which the organic structure MS is divided in a shape corresponding to that of the signal lines SLI, may have a narrow width, and the first organic pattern MSPa and the inorganic pattern MSPc of each of the division patterns MSP may not include the openings OPN according to the example embodiments described above. For example, in a portion where each signal line SLI and each division pattern MSP overlap, the first organic pattern MSPa and the inorganic pattern MSPc may entirely cover a signal line SLI corresponding to each division pattern MSP.

In case that the division patterns MSP have a narrow width, the first organic patterns MSPa may also have a narrow width. Therefore, the amount of gas released from the first organic patterns MSPa may be reduced. Accordingly, it is possible to reduce or prevent the inorganic patterns MSPc from being peeled off or delaminated without forming the openings OPN for outgassing in the division patterns MSP.

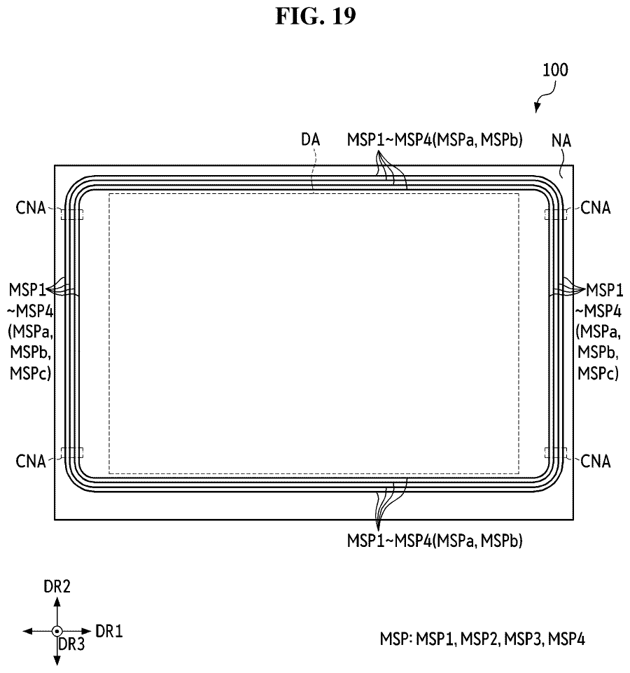

FIG. 19 is a plan view of a display panel 100 including an organic structure MS according to an example embodiment. For example, FIG. 19 shows an example embodiment of an organic structure MS which includes division patterns MSP as in the example embodiments of FIGS. 11 through 18.

Referring to FIG. 19 in addition to FIGS. 11 through 18, the organic structure MS may include division patterns MSP which are entirely separated from each other (e.g., completely separated from each other). The division patterns MSP may sequentially surround a display area DA.

In an example embodiment, the organic structure MS may include a first division pattern MSP1 surrounding the display area DA and a portion of a non-display area NA around the display area DA, a second division pattern MSP2 surrounding at least a portion of the first division pattern MSP1 at a position spaced apart from the first division pattern MSP1, a third division pattern MSP3 surrounding at least a portion of the second division pattern MSP2 at a position spaced apart from the second division pattern MSP2, and a fourth division pattern MSP4 surrounding at least a portion of the third division pattern MSP3 at a position spaced apart from the third division pattern MSP3. However, the number of division patterns MSP included in the organic structure MS may vary depending on example embodiments.

In an example embodiment, each division pattern MSP may have a closed planar shape (e.g., a ring shape, including a frame shape or a closed loop shape). For example, the first division pattern MSP1 may completely surround the display area DA, and the second division pattern MSP2 may completely surround the first division pattern MSP1. In addition, the third division pattern MSP3 may completely surround the second division pattern MSP2, and the fourth division pattern MSP4 may completely surround the third division pattern MSP3. However, example embodiments are not limited to this example. For example, at least one division pattern MSP may have an open structure.

Each division pattern MSP may include at least one organic pattern. For example, each division pattern MSP may include a first organic pattern MSPa and a second organic pattern MSPb.

In an example embodiment, each division pattern MSP may further include an inorganic pattern MSPc. For example, each division pattern MSP may include an inorganic pattern MSPc located on the first organic pattern MSPa in a portion overlapping signal lines SLI (e.g., a portion located on a side of each of the gate drivers GD of FIG. 2). For example, each division pattern MSP may include an inorganic pattern MSPc which covers the first organic pattern MSPa around a left edge and a right edge of the display panel 100. In an example embodiment, the inorganic pattern MSPc may not be located around an upper edge and a lower edge of the display panel 100. In this case, each division pattern MSP may have a three-layer structure including the first organic pattern MSPa, the inorganic pattern MSPc and the second organic pattern MSPb around the left edge and the right edge of the display panel 100 and may have a two-layer structure including the first organic pattern MSPa and the second organic pattern MSPb around the upper edge and the lower edge of the display panel 100.

In an example embodiment, the inorganic pattern MSPc may be a conductive pattern including a conductive material and may be electrically connected to a wiring located under the organic structure MS in at least one contact area CNA. For example, both ends of the inorganic pattern MSPc may be located in the contact areas CNA, and the inorganic pattern MSPc may be electrically connected to a signal line SLI under the inorganic pattern MSPc through a contact hole in each of the contact areas CNA. Accordingly, potentials of the inorganic pattern MSPc and the signal line SLI overlapping each other may become substantially the same, and the operation of the display device 1 may be stabilized.

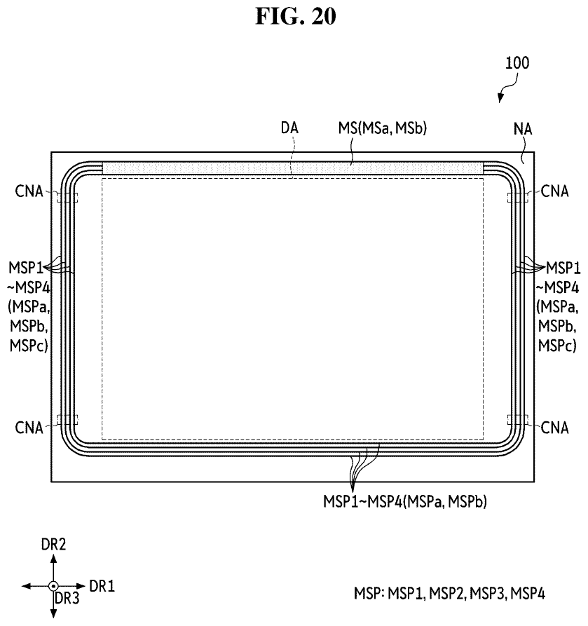

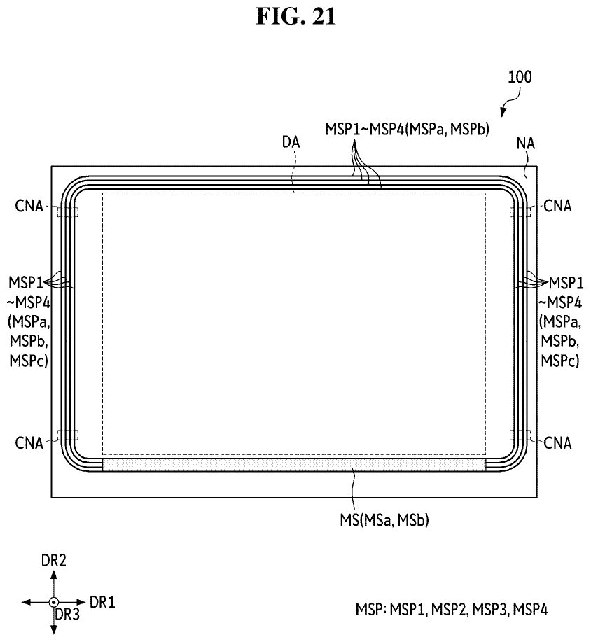

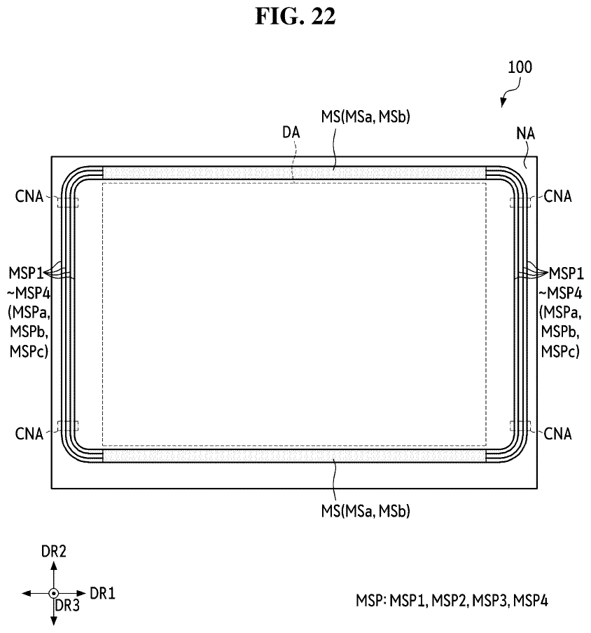

FIG. 20 is a plan view of a display panel including an organic structure according to an example embodiment. FIG. 21 is a plan view of a display panel including an organic structure according to an example embodiment. FIG. 22 is a plan view of a display panel including an organic structure according to an example embodiment. For example, FIGS. 20 through 22 show some example embodiments different from the embodiment of FIG. 19 in relation to an organic structure MS including division patterns MSP as in the example embodiments of FIGS. 11 through 18.

Referring to FIGS. 20 through 22 in addition to FIGS. 11 through 19, an organic structure MS may be divided into division patterns MSP only in a portion and may be integrated into one pattern in another portion. For example, the organic structure MS may be divided into division patterns MSP in one portion including a portion overlapping a plurality of signal lines SLI, and in another portion, portions extending (e.g., extending integrally) from the division patterns MSP may be integrated into one pattern.

In an example embodiment, as illustrated in FIG. 20, the organic structure MS may be integrated into one pattern in a portion of a non-display area NA which is located on an upper side of a display area DA and may be divided into division patterns MSP in other portions (e.g., portions of the non-display area NA which are located on lower, left and right sides of the display area DA). In an example embodiment, as illustrated in FIG. 21, the organic structure MS may be integrated into one pattern in a portion of the non-display area NA which is located on the lower side of the display area DA and may be divided into division patterns MSP in other portions (e.g., portions of the non-display area NA which are located on the upper, left and right sides of the display area DA). In an example embodiment, as illustrated in FIG. 22, the organic structure MS may be integrated into one pattern in portions of the non-display area NA which are located on the upper and lower sides of the display area DA and may be divided into division patterns MSP in other portions (e.g., portions of the non-display area NA which are located on the left and right sides of the display area DA). The organic structure MS may have a two-layer structure including a first organic layer MSa and a second organic layer MSb in a portion where it is integrated into one pattern.

When the organic structure MS is integrated into one pattern in an area where the signal lines SLI are not located, a bonding area between the organic structure MS and a mask may be increased. In addition, the durability (e.g., mechanical strength) of the organic structure MS may be improved.

In a portion where the organic structure MS is integrated into one pattern, the organic structure MS may have a multilayer structure including the first organic layer MSa and the second organic layer MSb. In a portion where the organic structure MS is divided into division patterns MSP, the organic structure MS may have a multilayer structure including first organic patterns MSPa and second organic patterns MSPb included in the division patterns MSP. In a portion where the organic structure MS overlaps the signal lines SLI and is divided into division patterns MSP, the organic structure MS may further include inorganic patterns MSPc included in the division patterns MSP.

According to the example embodiments of FIGS. 11 through 22, in a portion where the signal lines SLI and the organic structure MS overlap, the organic structure MS may be divided into shapes corresponding to the signal lines SLI. For example, the organic structure MS may be divided into shapes corresponding to the signal lines SLI and may include division patterns MSP overlapping different signal lines SLI, respectively.

The division patterns MSP of the organic structure MS according to the example embodiments may be only partially or entirely separated from each other. For example, the organic structure MS may include a plurality of division patterns MSP which are completely separated or spaced apart from each other. In some example embodiments, the organic structure MS may be divided into division patterns MSP only in a portion including a portion overlapping the signal lines SLI and may be formed as one integrated pattern in other portions.

According to the display device 1 including the organic structure MS according to the example embodiments, because the organic structure MS is divided into shapes corresponding to the signal lines SLI, the mutual influence between different signal lines SLI can be eliminated or reduced, and a difference in electrical characteristics (e.g., RC delay between the signal lines SLI) can be prevented or reduced. For example, even if the capacitance of at least one signal line SLI is changed as the dielectric constant of the organic structure MS is changed by outside air, the change in the capacitance of the at least one signal line SLI may be prevented or reduced from causing a change in the capacitance of other nearby signal lines SLI. Accordingly, a change in the characteristics (e.g., a change in the capacitance) of the signal lines SLI can be prevented or reduced.

In some example embodiments, the organic structure MS may include the inorganic patterns MSPc which cover the first organic patterns MSPa of the division patterns MSP. Accordingly, the inorganic patterns MSPc may protect the first organic patterns MSPa during an ashing process, etc. performed in a process of forming the organic structure MS. For example, the first organic patterns MSPa may be portions covered with the inorganic patterns MSPc during the ashing process and may be portions in which a change in characteristics due to the ashing process is prevented or reduced. Accordingly, an organic structure MS that is more robust to moisture absorption can be formed, and a change in characteristics (e.g., a change in dielectric constant, etc.) of the organic structure MS can be prevented or reduced.

According to the display device 1 including the organic structure MS according to the example embodiments, a difference in RC delay between signals transmitted to a gate driver GD through the signal lines SLI (e.g., clock signals CK input to the gate driver GD) can be prevented or reduced, and the operating characteristics of the gate driver GD can be improved. Accordingly, it is possible to prevent or alleviate image quality defects, such as horizontal line defects, and improve the image quality of the display device 1.

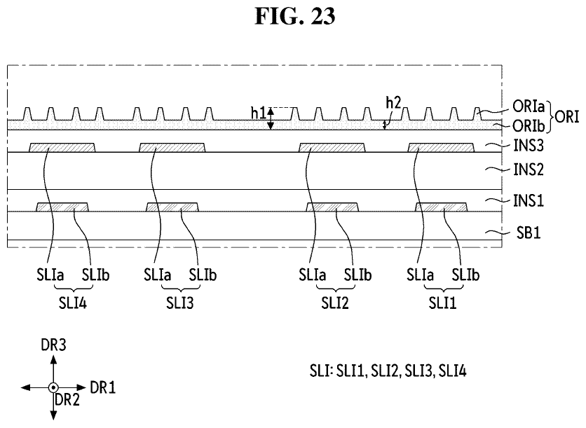

FIGS. 23 through 26 are cross-sectional views illustrating a method of manufacturing a display device according to an example embodiment. For example, FIGS. 23 through 26 sequentially show manufacturing operations for forming an organic structure MS, which includes division patterns MSP including openings OPN as in the example embodiments of FIGS. 11 through 16, among manufacturing operations for manufacturing a display panel 100 of a display device 1. FIGS. 23 through 26 show the manufacturing operations for forming the organic structure MS through cross-sections at a position corresponding to line X1-X1′ of FIG. 12.

Referring to FIG. 23 in addition to FIGS. 1 through 22, signal lines SLI, a third insulating layer INS3, and an organic film ORI may be sequentially formed on a first substrate SB1. For example, after a backplane layer BPL including the signal lines SLI and the third insulating layer INS3 is formed on the first substrate SB1, the organic film ORI may be formed on the third insulating layer INS3.

In an example embodiment, as illustrated in FIG. 5, the backplane layer BPL may include a first conductive layer CDL1, a first insulating layer INS1, a semiconductor layer SCL, a gate insulating layer GI, a second conductive layer CDL2, a second insulating layer INS2, a third conductive layer CDL3, and the third insulating layer INS3. In this case, the backplane layer BPL may be formed by forming the first conductive layer CDL1, the first insulating layer INS1, the semiconductor layer SCL, the gate insulating layer GI, the second conductive layer CDL2, the second insulating layer INS2, the third conductive layer CDL3, and the third insulating layer INS3 on the first substrate SB1. At least one of the insulating layers included in the backplane layer BPL may be formed on the entire surface of the first substrate SB1 across a display area DA and a non-display area NA. For example, the first insulating layer INS1, the second insulating layer INS2, and the third insulating layer INS3 may be formed on the entire surface of the first substrate SB1 across the display area DA and the non-display area NA.

In an example embodiment, each of the signal lines SLI may be formed as a multilayer including a main wiring layer SLIa included in the third conductive layer CDL3 and a sub-wiring layer SLIb included in the first conductive layer CDL1. In this case, the sub-wiring layer SLIb of each of the signal lines SLI may be formed in an operation of forming the first conductive layer CDL1, and the main wiring layer SLIa of each of the signal lines SLI may be formed in an operation of forming the third conductive layer CDL3. The first insulating layer INS1 and the second insulating layer INS2 may be located between the sub-wiring layer SLIb and the main wiring layer SLIa of each of the signal lines SLI. The sub-wiring layer SLIb and the main wiring layer SLIa of each of the signal lines SLI may be electrically connected to each other through at least one contact hole (e.g., contact holes CNT of FIG. 12) penetrating the first insulating layer INS1 and the second insulating layer INS2. The main wiring layer SLIa of each of the signal lines SLI may be covered with the third insulating layer INS3.

The organic film ORI may be formed on the entire surface of the third insulating layer INS3 across the display area DA and the non-display area NA to form an organic layer ORL of the display area DA, a dam structure DM and an organic structure MS of the non-display area NA, etc. The organic film ORI may be formed using an organic insulating material, which is described as an example for the material of the organic layer ORL of the display area DA, but example embodiments are not limited to this case.

In an example embodiment, the organic film ORI may be formed to different thicknesses or heights in different portions by using a halftone mask. For example, the organic film ORI may be formed to a first height h1 (or a first thickness) in a portion corresponding to an area where an inorganic pattern MSPc is to be formed in a subsequent process and may be formed to a second height h2 (or a second thickness), which is lower than the first height h1, in another portion. Accordingly, the organic film ORI may include a first portion ORIa having the first height h1 and a second portion ORIb having the second height h2. For example, the second portion ORIb of the organic film ORI may be a portion corresponding to a halftone portion of the halftone mask and may be a portion formed to a lower (e.g., smaller) thickness or height than the first portion ORIa. On the other hand, the first portion ORIa of the organic film ORI may be a portion covered by an opaque portion of the halftone mask, such as chrome, and thus may be formed to a higher (e.g., greater) thickness or height than the second portion ORIb. In an example embodiment, a full-tone portion of the halftone mask may be placed on a portion where a via hole VH is desired to be formed in an organic layer ORL and the third insulating layer INS3 for connection between a first electrode AE of a light emitting element EL and a source electrode SE of a first transistor T1 as illustrated in FIG. 5. Accordingly, the via hole VH may be formed in the organic layer ORL and the third insulating layer INS3 before the first electrode AE of the light emitting element EL is formed. For example, portions of the halftone mask which have different characteristics (e.g., the full-tone portion, the halftone portion and the chrome portion of the halftone mask) may be placed on a portion where the organic film ORI and the third insulating layer INS3 are to be removed together, a portion where the organic film ORI is to be removed and the third insulating layer INS3 is to be left, and a portion where both the organic film ORI and the third insulating layer INS3 are to be left. Therefore, the organic film ORI can be formed into a desired shape while the mask process is reduced or minimized.

The second portion ORIb of the organic film ORI may include a portion where the organic film ORI is to be opened or removed, for example, an area where the openings OPN of FIGS. 13 and 14 are to be formed. For example, the halftone portion of the halftone mask may be placed on the portion where the organic film ORI is to be removed.

In an example embodiment, the second portion ORIb of the organic film ORI may further include a portion around the area where the openings OPN are to be formed. For example, the second portion ORIb of the organic film ORI may be formed to a width that can overlap ends of an inorganic pattern MSPc.

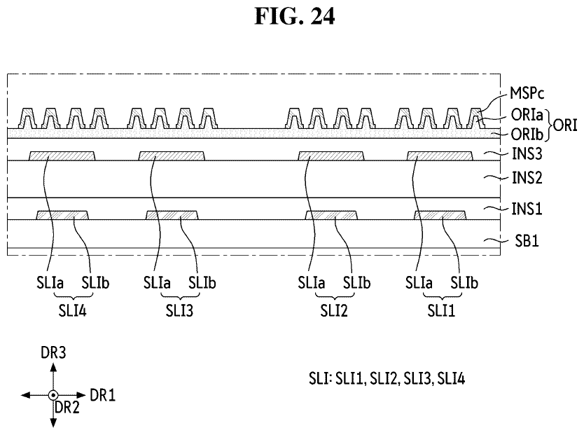

Referring to FIG. 24, inorganic patterns MSPc may be formed on the organic film ORI. The inorganic patterns MSPc may be formed on a portion of the organic film ORI including the first portion ORIa and may be spaced apart from each other in the first direction DR1.

In an example embodiment, the inorganic patterns MSPc may be formed to further cover ends of the second portion ORIb of the organic film ORI. For example, ends of the inorganic patterns MSPc may be located on the second portion ORIb of the organic film ORI. Accordingly, portions of the organic film ORI, whose chemical properties are changed in a subsequent ashing process, may all be removed.

In an example embodiment, the inorganic patterns MSPc may be formed together with the first electrode AE of each of the light emitting elements EL located in the display area DA in an operation of forming the first electrode AE. For example, a single-layer or multilayer conductive film including at least one conductive material may be formed across the display area DA and the non-display area NA, and the first electrodes AE of the light emitting elements EL may be formed by etching the conductive film. In this case, the inorganic patterns MSPc may be formed using a conductive material, which is described as an example for the material of the first electrode AE of each of the light emitting elements EL. In addition, the first electrode AE of each of the light emitting elements EL and the inorganic patterns MSPc may have the same cross-sectional structure (e.g., a single-layer structure or a multilayer structure).

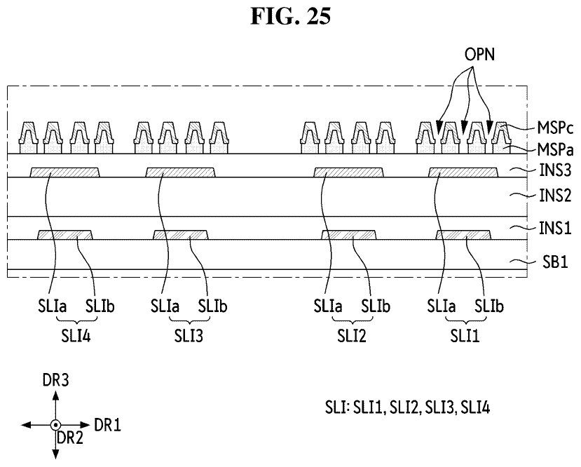

Referring to FIG. 25, first organic patterns MSPa may be formed using the inorganic patterns MSPc as a mask. For example, an ashing process for removing portions of the organic film ORI may be performed using the inorganic patterns MSPc as a hard mask. Accordingly, portions of the organic film ORI which are not covered with the inorganic patterns MSPc may be removed. For example, portions of the second portion ORIb of the organic film ORI which are not covered with the inorganic patterns MSPc may be removed. Thus, the organic film ORI may be divided into the first organic patterns MSPa, and the openings OPN may be formed in the first organic patterns MSPa.

When the organic film ORI is patterned into the first organic patterns MSPa using the inorganic patterns MSPc as a mask, the first organic patterns MSPa having a shape and/or size corresponding to a shape and/or size of the inorganic patterns MSPc may be formed under the inorganic patterns MSPc. In an example embodiment, the first organic patterns MSPa may be formed to have a slightly smaller width than the inorganic patterns MSPc, but example embodiments are not limited to this case. For example, the first organic patterns MSPa and the inorganic patterns MSPc may be formed to have substantially the same or similar shape and/or size, and the shapes and/or sizes of the first organic patterns MSPa and the inorganic patterns MSPc may become slightly different depending on the environment or conditions in which the ashing process is performed.

According to the above-described example embodiment, because the ashing process is performed on the organic film ORI while the first organic patterns MSPa are covered with the inorganic patterns MSPc, the first organic patterns MSPa can be appropriately or effectively protected during the ashing process. For example, the first organic patterns MSPa are formed from portions of the organic film ORI which are covered with the inorganic patterns MSPc during the ashing process. Therefore, the first organic patterns MSPa may be portions where a change in chemical properties due to the ashing process is prevented or minimized or reduced. In an area where the organic structure MS is formed, portions where the chemical properties of the organic film ORI are changed by the ashing process may be portions which are not covered with the inorganic patterns MSPc and may be portions which are removed by the ashing process. Accordingly, the first organic patterns MSPa can be prevented or reduced from becoming vulnerable to moisture, and an organic structure MS that is more robust to moisture absorption can be formed. For example, the first organic patterns MSPa can be reduced or prevented from becoming vulnerable to moisture absorption by the ashing process, and the possibility of moisture absorption of the first organic patterns MSPa can be eliminated or reduced. Accordingly, it is possible to prevent or alleviate image quality defects (e.g., horizontal line defects) which may occur due to outside air, etc. being absorbed by the organic structure MS.

In an example embodiment, a portion of the organic layer ORL in the display area DA may also be removed by the ashing process of the organic film ORI. For example, as in FIG. 5, the organic layer ORL may be removed by a certain thickness in a portion not covered by the first electrode AE of each of the light emitting elements EL. Accordingly, the organic layer ORL may have a relatively low height in the portion not covered by the first electrode AE. In an example embodiment, as in FIG. 8, even in a portion where the organic film ORI is to be removed, such as a space between dams (e.g., an opening OP1 between a first dam DM1 and a second dam DM2), the organic film ORI may first be formed to the second height h2 and then may be removed in the ashing process.

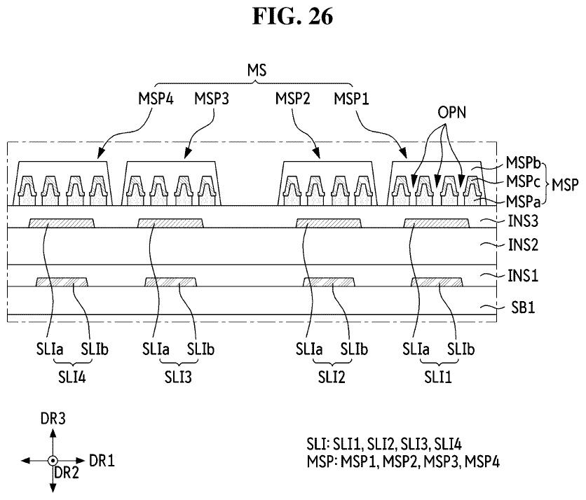

Referring to FIG. 26, second organic patterns MSPb may be formed on the first organic patterns MSPa and the inorganic patterns MSPc, thereby forming an organic structure MS including division patterns MSP. In an example embodiment, the second organic patterns MSPb may have a shape and/or size corresponding to a shape and/or size of the division patterns MSP and may be spaced apart from each other in the first direction DR1.

In an example embodiment, the second organic patterns MSPb may not include openings having a shape corresponding to that of the openings OPN of the first organic patterns MSPa and the inorganic patterns MSPc. For example, in each division pattern MSP, a second organic pattern MSPb may entirely cover a first organic pattern MSPa and an inorganic pattern MSPc. In an example embodiment, the second organic pattern MSPb may have a greater width than the first organic pattern MSPa and the inorganic pattern MSPc and may cover upper and side surfaces of the first organic pattern MSPa and the inorganic pattern MSPc, but example embodiments are not limited to this case.

In an example embodiment, the second organic patterns MSPb may be formed together with a pixel defining layer PDL in an operation of forming the pixel defining layer PDL in the display area DA. For example, the pixel defining layer PDL and the second organic patterns MSPb may be formed simultaneously using an organic insulating material, which is described as an example for the material of the pixel defining layer PDL.

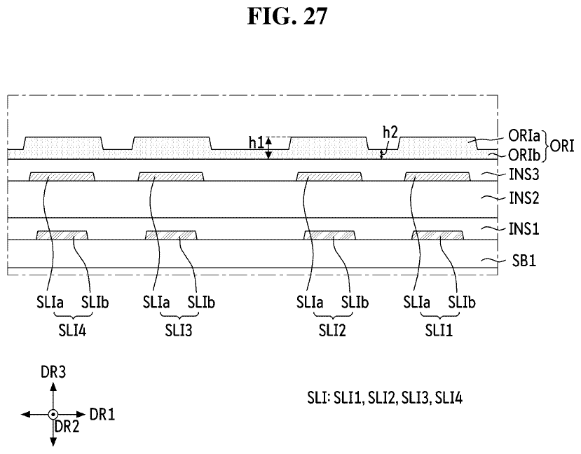

FIGS. 27 through 30 are cross-sectional views illustrating a method of manufacturing a display device according to an example embodiment. For example, FIGS. 27 through 30 sequentially show manufacturing operations for forming an organic structure MS, which includes division patterns MSP not including openings OPN, unlike in the embodiments of FIGS. 11 through 16, among manufacturing operations for manufacturing a display panel 100 of a display device 1. FIGS. 27 through 30 show the manufacturing operations for forming the organic structure MS through cross-sections at a position corresponding to line X1-X1′ of FIG. 12.

Referring to FIG. 27, an organic film ORI may be formed on a first substrate SB1. For example, after a backplane layer BPL including signal lines SLI and a third insulating layer INS3 is formed on the first substrate SB1, the organic film ORI may be formed on the third insulating layer INS3.

In an example embodiment, the organic film ORI may be formed to different thicknesses or heights in different portions by using a halftone mask. For example, the organic film ORI may be formed to a first height h1 on each signal line SLI and may be formed to a second height h2, which is lower than the first height h1, in another portion. Accordingly, the organic film ORI may include a first portion ORIa covering each signal line SLI and a second portion ORIb around the fist portion ORIa. In an example embodiment, in an area where an organic structure MS or each division pattern MSP is to be formed, the organic film ORI may be formed to a substantially uniform height or thickness on each signal line SLI and may have a substantially flat upper surface. A formation method or material of the organic film ORI may be the same as or substantially similar to that of the example embodiment of FIG. 23, and thus a detailed description thereof will be omitted.

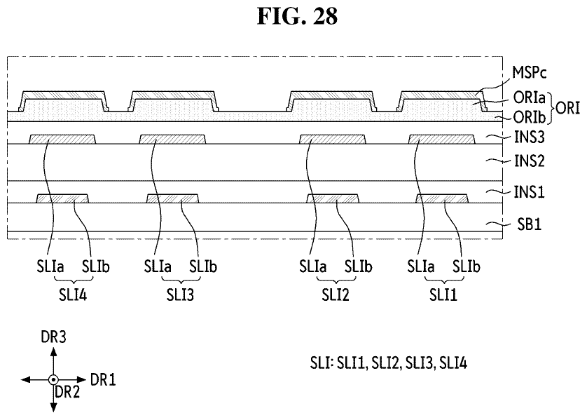

Referring to FIG. 28, inorganic patterns MSPc may be formed on the organic film ORI. The inorganic patterns MSPc may be formed to cover the first portion ORIa of the organic film ORI, and ends of the inorganic patterns MSPc may be located on the second portion ORIb of the organic film ORI. A formation method or material of the inorganic patterns MSPc may be the same as or substantially similar to that of the example embodiment of FIG. 24, and thus a detailed description thereof will be omitted.

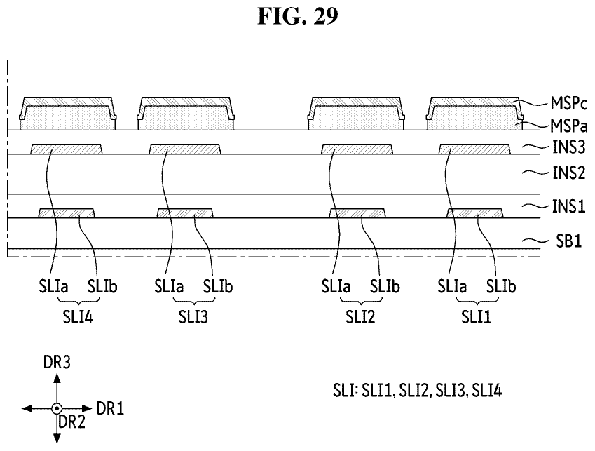

Referring to FIG. 29, first organic patterns MSPa may be formed using the inorganic patterns MSPc as a mask. For example, the organic film ORI may be patterned into the first organic patterns MSPa by an ashing process using the inorganic patterns MSPc as a mask. Accordingly, the first organic patterns MSPa having a shape and/or size corresponding to a shape and/or size of the inorganic patterns MSPc may be formed.

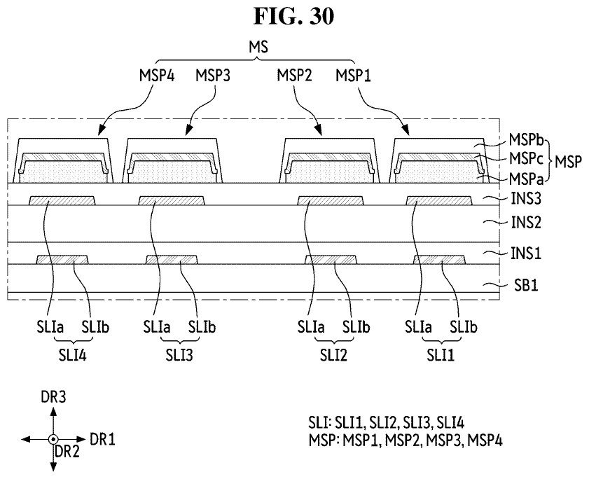

Referring to FIG. 30, second organic patterns MSPb may be formed on the first organic patterns MSPa and the inorganic patterns MSPc, thereby forming an organic structure MS including division patterns MSP. A formation method or material of the second organic patterns MSPb may be the same as or substantially similar to that of the example embodiment of FIG. 26, and thus a detailed description thereof will be omitted.

The display device 1 according to at least one of the example embodiments described above can be applied to various electronic devices. An electronic device according to an example embodiment includes the above-described display device 1 (or a display module including a display panel 100 according to at least one example embodiment) and may further include modules or devices having other additional functions, in addition to the display device 1.

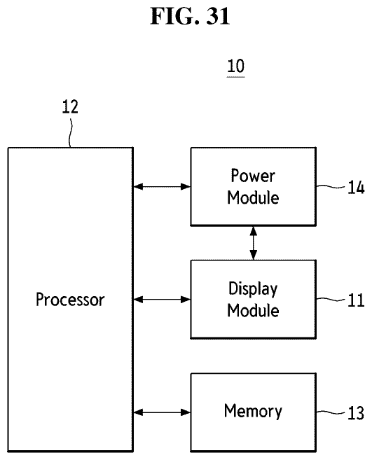

FIG. 31 is a block diagram of an electronic device 10 according to an example embodiment. Referring to FIG. 31, the electronic device 10 according to the example embodiment may include a display module 11, a processor 12, a memory 13, and a power module 14.

The electronic device 10 may output various information in the form of images through the display module 11. When the processor 12 executes an application stored in the memory 13, image information provided by the application may be provided to a user through the display module 11.

The display module 11 may include a display panel 100 for displaying an image. For example, the display module 11 may include a display panel 100 according to at least one of the example embodiments described above.

The processor 12 may include at least one of a central processing unit (CPU), an application processor (AP), a graphic processing unit (GPU), a communication processor (CP), an image signal processor (ISP), or a controller.

The memory 13 may store data information necessary or desired for the operation of the processor 12 or the display module 11. For example, the memory 13 may store an image data signal and/or an input control signal.

The processor 12 may control the display module 11 using information stored in the memory 13. The processor 12 may transmit an image data signal and/or an input control signal stored in the memory 13 to the display module 11. For example, when the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module, which generates power necessary or desired for the operation of the electronic device 10 by converting power supplied by the power supply module.

At least one of the elements of the electronic device 10 described above may be included in the display device 1 according to the above-described example embodiments. In addition, some of individual modules functionally included in one module may be included in the display device 1, and other modules may be provided separately from the display device 1. For example, the display device 1 may include the display module 11, and the processor 12, the memory 13 and the power module 14 may be provided not in the display device 1, but in the form of other devices within the electronic device 10.

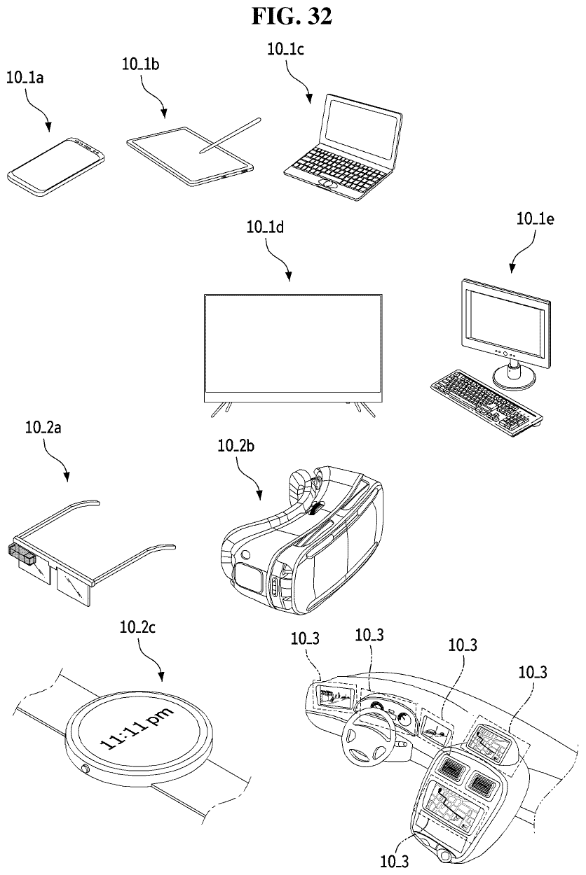

FIG. 32 is a schematic diagram of electronic devices according to various example embodiments.

Referring to FIG. 32, various electronic devices to which a display device 1 according to one of the above example embodiments is applied may include not only image display electronic devices, such as a smartphone 10_1a, a tablet PC 10_1b, a laptop 10_1c, a television 10_1d and a desk monitor 10_1e, but also wearable electronic devices including a display module, such as smart glasses 10_2a, a head-mounted display 10_2b and a smart watch 10_2c, and vehicle electronic devices 10_3 including a display module, such as a center information display (CID) and a room mirror display placed on an instrument panel, a center fascia and a dashboard of a vehicle.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications can be made to the example embodiments set forth above without substantially departing from the principles of the present inventive concepts. Therefore, the disclosed example embodiments of the inventive concepts are used in a generic and descriptive sense only and not for purposes of limitation.

What is claimed is:

1. A display device comprising:
a substrate comprising a display area and a non-display area;
pixels on the substrate in the display area;
signal lines on the substrate in the non-display area; and
an organic structure on a plurality of signal lines among the signal lines, the organic structure comprising division patterns, the division patterns having a shape corresponding to that of the plurality of signal lines.

2. The display device of claim 1, wherein
the plurality of signal lines comprise a first signal line and a second signal line arranged in series in a first direction, and
the division patterns comprise a first division pattern and a second division pattern, the first division pattern and the second division pattern being on the first signal line and the second signal line, respectively, and spaced apart from each other in the first direction.

3. The display device of claim 2, further comprising:
a gate driver on the substrate and in the non-display area, the gate driver electrically connected to the first signal line and the second signal line,
wherein the first signal line and the second signal line are clock signal lines configured to receive different clock signals.

4. The display device of claim 3, wherein the organic structure surrounds the display area and the gate driver.

5. The display device of claim 1, wherein the organic structure comprises a number of division patterns corresponding to a number of the plurality of signal lines.

6. The display device of claim 1, wherein each of the division patterns comprises:
a first organic pattern on each of the plurality of signal lines;
an inorganic pattern covering an upper surface of the first organic pattern; and
a second organic pattern on the first organic pattern and the inorganic pattern.

7. The display device of claim 6, wherein the inorganic pattern comprises a plurality of openings.

8. The display device of claim 7, wherein the first organic pattern has a shape corresponding to that of the inorganic pattern and is opened in areas corresponding to the plurality of openings.

9. The display device of claim 6, wherein the first organic pattern has a first height under a central portion of the inorganic pattern and has a second height under both ends of the inorganic pattern, the second height being lower than the first height.

10. The display device of claim 6, further comprising:
an insulating layer between the signal lines and the organic structure and covering the signal lines; and
an organic layer on the insulating layer in the display area,
wherein each of the pixels comprises a light emitting element, the light emitting element comprising a first electrode, a light emitting layer and a second electrode sequentially located on the organic layer.

11. The display device of claim 10, wherein
the first organic pattern is on the insulating layer and comprises a same material as the organic layer, and
the inorganic pattern comprises a same material as the first electrode included in the light emitting element.

12. The display device of claim 10, further comprising:
a pixel defining layer on the organic layer in the display area and covering an edge portion of the first electrode of the light emitting element,
wherein the second organic pattern comprises a same material as the pixel defining layer.

13. The display device of claim 1, wherein the division patterns are entirely separated from each other and sequentially surround the display area.

14. The display device of claim 1, wherein
in one portion of the non-display area that overlaps the plurality of signal lines, the organic structure is divided into the division patterns, and
in another potion of the non-display area, the organic structure is provided as an integral structure by integrating portions extending from the division patterns into one pattern.

15. An electronic device comprising:
a display module comprising a display panel; and
a processor configured to transmit an image data signal to the display module,
wherein the display panel comprises
a substrate comprising a display area and a non-display area,
pixels on the substrate in the display area,
signal lines on the substrate in the non-display area, and
an organic structure on a plurality of signal lines among the signal lines, the organic structure comprising division patterns, the division patterns having a shape corresponding to that of the plurality of signal lines.

16. The electronic device of claim 15, wherein
the plurality of signal lines comprise a first signal line and a second signal line arranged in series in a first direction, and
the division patterns comprise a first division pattern and a second division pattern, the first division pattern and the second division pattern being on the first signal line and the second signal line, respectively, and spaced apart from each other in the first direction.

17. The electronic device of claim 15, wherein each of the division patterns comprises:
a first organic pattern on each of the plurality of signal lines;
an inorganic pattern covering an upper surface of the first organic pattern; and
a second organic pattern on the first organic pattern and the inorganic pattern.

18. A method of manufacturing a display device, the method comprising:
sequentially forming signal lines, an insulating layer and an organic structure on a substrate, the forming of the organic structure comprising
forming an organic film on the insulating layer, the organic film including a first portion having a first height and a second portion having a second height lower than the first height,
forming inorganic patterns on a first area of the organic film that includes the first portion and to be spaced apart from each other in a first direction,
forming first organic patterns under the inorganic patterns by removing a second area of the organic film that is not covered with the inorganic patterns, by an ashing process using the inorganic patterns as a mask, and
forming second organic patterns on the first organic patterns and the inorganic patterns and to be spaced apart from each other in the first direction.

19. The method of claim 18, wherein the first organic patterns, the inorganic patterns and the second organic patterns are formed on a plurality of signal lines that are sequentially arranged in the first direction, and are divided into shapes corresponding to the plurality of signal lines.

20. The method of claim 18, wherein the first organic patterns and the inorganic patterns are formed on respective ones of the signal lines and comprise a plurality of openings.
